(19) United States
(12) Patent Application Publication
(10) Pub. No.: US 2016/0146995 A1
(43) Pub. Date: May 26, 2016

(54) OPTICAL FILM

(71) Applicant: SUMITOMO CHEMICAL COMPANY, LIMITED, Tokyo (JP)

(72) Inventors: Tatsuaki KASAI, Osaka-shi (JP); Tadahiro KOBAYASHI, Osaka-shi (JP)

(73) Assignee: SUMITOMO CHEMICAL COMPANY, LIMITED, Tokyo (JP)

(21) Appl. No.: 14/949,186

(22) Filed: Nov. 23, 2015

(30) Foreign Application Priority Data
Nov. 26, 2014 (JP) 2014-238558

(51) Int. Cl. G02B 5/30; B05D 3/06; H01L 51/52

(52) U.S. Cl. CPC G02B 5/3016; H01L 51/5293; B05D 3/065

(57) ABSTRACT

A flat panel display device (FPD) makes use of a member including an optical film such as a polarizing plate or a retardation plate. As such an optical film, known is an optical film produced by applying a composition containing a polymerizable liquid crystal compound to a substrate. However, in a conventional optical film, retardation unevenness is generated in a film plane and an optical compensation characteristic for suppressing light leakage attributed to such retardation unevenness during black display of a display device is not sufficient. The present invention, therefore, provides an optical film having an orientation layer containing a leveling agent and an optically anisotropic layer formed on the orientation layer.

### BACKGROUND OF THE INVENTION

1. Field of the Invention

The present invention relates to an optical film having an optically anisotropic layer.

2. Description of the Related Art

A flat panel display device (FPD) makes use of a member including an optical film such as a polarizing plate or a retardation plate. As such an optical film, known is an optical film produced by applying a composition containing a polymerizable liquid crystal compound to a substrate. For example, JP-T-2010-537955 describes an optical film exhibiting a reverse-wavelength dispersion property.

### SUMMARY OF THE INVENTION

However, in a conventional optical film, retardation unevenness is generated in a film plane and an optical compensation characteristic for suppressing light leakage attributed to such retardation unevenness during black display of a display device is not sufficient.

The present invention includes the following.

[1] An optical film having a orientation layer containing a leveling agent and an optically anisotropic layer.
[2] The optical film according to [1], wherein a content of the leveling agent in the orientation layer is not less than 0.001 parts by mass and not more than 5 parts by mass to 100 parts by mass of a solid matter in a composition for forming an orientation layer to form an orientation layer.
[3] The optical film according to [1] or [2], wherein the orientation layer has a thickness of not less than 10 nm and not more than 1000 nm.
[4] The optical film according to any of [1] to [3], wherein the orientation layer is a photo-orientation layer.
[5] The optical film according to any of [1] to [4], wherein the orientation layer includes a structure derived from a compound having a cinnamoyl group.
[6] The optical film according to any of [1] to [5], wherein the optically anisotropic layer has optical characteristics defined by the formulas (1) and (2):

Re(450)/Re(550)≦1.00 (1)

1.00≦Re(650)/Re(550) (2)

wherein, Re(λ) represents an in-plane retardation value to light with a wavelength of λ nm.
[7] The optical film according to any of [1] to [6], wherein the optically anisotropic layer has an optical characteristic defined by the formula (3):

100 nm<Re(550)<160 nm (3)

wherein, Re(550) represents an in-plane retardation value at a wavelength of 550 nm.
[8] The optical film according to any of [1] to [7], wherein the optically anisotropic layer contains a polymer of one or more polymerizable liquid crystal compounds.
[9] The optical film according to any of [1] to [8], wherein the optically anisotropic layer has a thickness of not more than 20 μm.
[10] A circularly polarizing plate comprising a layer including at least the optically anisotropic layer of the optical film according to any of [1] to [9] and a polarizing film.
[11] The circularly polarizing plate according to [10], wherein the layer including at least the optically anisotropic layer and the polarizing plate are bonded to each other with an active energy ray-curing adhesive or a water-based adhesive.
[12] An organic EL display device comprising the circularly polarizing plate according to [10] or [11].
[13] A touch panel display device comprising the circularly polarizing plate according to [10] or [11].
[14] A method for producing an optical film having an orientation layer containing a leveling agent and an optically anisotropic layer formed on the orientation layer, the method comprising the step of generating orientation regulation force on the orientation layer by irradiation of not less than 10 mJ/cm² and not more than 200 mJ/cm² of ultraviolet rays.

The present invention can provide an optical film excellent in suppression of light leakage during black display of a display device.

### BRIEF DESCRIPTION OF THE DRAWINGS

FIG. 1 is schematic cross-sectional diagrams showing one example of the optical film of the present invention;

FIG. 2 is schematic cross-sectional diagrams showing one example of a circularly polarizing plate including the optical film of the present invention; and

FIG. 3 is schematic cross-sectional diagrams showing one example of an organic EL display device including the optical film of the present invention.

### DETAILED DESCRIPTION OF THE PREFERRED EMBODIMENTS

The optical film of the present invention (hereinafter, may be referred to as the present optical film) is an optical film having an orientation layer and an optically anisotropic layer formed on the orientation layer and is characterized in that the orientation layer contains a leveling agent. The orientation layer contains a leveling agent so that an effect of an excellent optical compensation characteristic is exerted when the present optical film is incorporated in a display device.

Hereinafter, each member constituting the present optical film will be described.

### [Optically Anisotropic Layer]

Examples of the optically anisotropic layer include a layer formed by polymerizing a polymerizable liquid crystal compound, and a stretched film. The optical characteristics of the optically anisotropic layer can be adjusted by orientation state of the polymerizable liquid crystal compound or a method for stretching the stretched film.

In this description, horizontal orientation is defined such that the optical axis of the polymerizable liquid crystal compound is oriented horizontally to the substrate flat plane when the polymerizable liquid crystal compound is applied to the substrate, and perpendicular orientation is defined such that the optical axis of the polymerizable liquid crystal compound is oriented perpendicularly to the substrate flat plane. The optical axis means a direction in which no birefringence is generated in anisotropic crystals. In an index ellipsoid formed by orientation of the polymerizable liquid crystal compound, if one optical axis exists, the cross section orthogonal to the optical axis becomes a circle.

Examples of the polymerizable liquid crystal compound include rod-shaped polymerizable liquid crystal compounds and disk-shaped polymerizable liquid crystal compounds.

When a rod-shaped polymerizable liquid crystal compound is oriented horizontally or perpendicularly to the substrate, that is, when the major axis of the polymerizable liquid crystal compound is oriented horizontally or perpendicularly to the substrate, the optical axis of the polymerizable liquid crystal compound is coincident with the major axis direction of the polymerizable liquid crystal compound.

When a disk-shaped polymerizable liquid crystal compound is oriented, the optical axis of the polymerizable liquid crystal compound exists in the direction orthogonal to the disk plane of the polymerizable liquid crystal compound.

The slow axis direction of the stretching film differs depending on the stretching method. The slow axis and the optical axis are determined depending on a stretching method, e.g., uniaxial, biaxial, or diagonal stretching.

In order to generate in-plane retardation in a layer formed by polymerizing a polymerizable liquid crystal compound, the polymerizable liquid crystal compound should be oriented in an adequate direction. When the polymerizable liquid crystal compound is in rod-shaped, horizontal orientation of the optical axis of the polymerizable liquid crystal compound to the substrate flat plane generates in-plane retardation. In this case, the optical axis direction and the slow axis direction are coincident with each other. When the polymerizable liquid crystal compound is in disk-shaped, horizontal orientation of the optical axis of the polymerizable liquid crystal compound to the substrate flat plane generates in-plane retardation. In this case, the optical axis direction and the slow axis direction are orthogonal to each other. The orientation state of the polymerizable liquid crystal compound can be adjusted by combination of the orientation layer and the polymerizable liquid crystal compound.

The in-plane retardation value of the optically anisotropic layer can be adjusted based on the thickness of the optically anisotropic layer. Since the in-plane retardation value can be determined according to the formula (10), Δn(λ) and layer thickness d should be adjusted for obtaining a desired in-plane retardation value (Re(λ)):

Re(λ)=d×Δn(λ) (10)

wherein, Re(λ) represents an in-plane retardation value at a wavelength of λ nm, d represents a layer thickness, and Δn(λ) represents a birefringence at a wavelength of λ nm.

The birefringence Δn(λ) is obtained by measuring the in-plane retardation value and dividing the in-plane retardation value by the thickness of the optically anisotropic layer. Although a specific measurement method is shown in Examples, at this time, when a film formed on a substrate having no in-plane retardation in itself, such as a glass substrate, is subjected to the measurement, the substantial characteristics of the optically anisotropic layer can be measured.

In this description, the refractive indexes of three axes in a refractive index ellipsoid formed by orientation of a polymerizable liquid crystal compound or stretching of a film are denoted as nx, ny, and nz, respectively. nx represents the main refractive index of the axis parallel to the film flat plane in a refractive index ellipsoid which the optically anisotropic layer forms. ny represents the refractive index of the axis parallel to the film flat plane and orthogonal to nx in the refractive index ellipsoid which the optically anisotropic layer forms. nz represents the refractive index of the axis orthogonal to the film flat plane in the refractive index ellipsoid which the optically anisotropic layer forms.

When the optical axis of the rod-shaped polymerizable liquid crystal compound is oriented horizontally to the substrate flat plane, the relation of the refractive indexes of the optically anisotropic layer to be obtained is defined as nx>ny≈nz (positive A plate), and nx and the slow axis are coincident with each other.

When the optical axis of the disk-shaped polymerizable liquid crystal compound is oriented horizontally to the substrate flat plane, the relation of the refractive indexes of the optically anisotropic layer to be obtained is defined as nx<ny≈nz (negative A plate), and ny and the slow axis are coincident with each other.

### <Polymerizable Liquid Crystal Compound>

The polymerizable liquid crystal compound is a compound having a polymerizable group and having a liquid crystal property. The polymerizable group used here in means a group that is involved in a polymerization reaction, and the group is preferably a photopolymerizable group. The photopolymerizable group used herein is a group that can be involved in a polymerization reaction through an active radical, an acid or the like resulting from a photopolymerization initiator described below. Examples of the polymerizable group include a vinyl group, a vinyloxy group, a 1-chlorovinyl group, an isopropenyl group, a 4-vinylphenyl group, an acryloyloxy group, a methacryloyloxy group, an oxiranyl group and an oxetanyl group. Among them, an acryloyloxy group, a methacryloyloxy group, a vinyloxy group, an oxiranyl group or an oxetanyl group is preferable, and an acryloyloxy group is more preferable. A liquid crystal property which the polymerizable liquid crystal compound has may be a thermotropic liquid crystal or a lyotropic liquid crystal, and in classification based on the degree of order, such a thermotropic liquid crystal may be a nematic liquid crystal or a smectic liquid crystal.

Examples of the rod-shaped polymerizable liquid crystal compound include a compound represented by the following formula (A) (hereinafter, may be referred to as a polymerizable liquid crystal (A)) and a compound containing a group represented by the following formula (X) (hereinafter, may be referred to as a polymerizable liquid crystal (B)).

### <Polymerizable Liquid Crystal A>

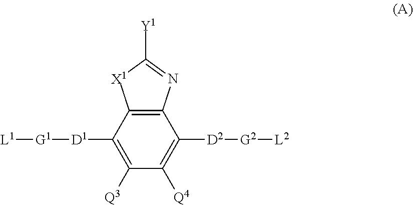

In the formula (A),

X¹ represents an oxygen atom, a sulfur atom, or —NR¹—, and R¹ represents a hydrogen atom or an alkyl group having 1 to 4 carbon atoms,

Y¹ represents an optionally substituted monovalent aromatic hydrocarbon group having 6 to 12 carbon atoms or an optionally substituted monovalent aromatic heterocyclic group having 3 to 12 carbon atoms,

Q³ and Q⁴ each independently represent a hydrogen atom, an optionally substituted monovalent aliphatic hydrocarbon group having 1 to 20 carbon atoms, a monovalent alicyclic hydrocarbon group having 3 to 20 carbon atoms, an optionally substituted monovalent aromatic hydrocarbon group having 6 to 20 carbon atoms, a halogen atom, a cyano group, a nitro group, —NR₂R³, or —SR², or Q³ and Q⁴ are bonded to each other to form an aromatic ring or a aromatic heterocyclic ring together with the carbon atom to which they are bonded, R² and R³ each independently represent a hydrogen atom or an alkyl group having 1 to 6 carbon atoms,

D¹ and D² each independently represent a single bond, —CO—O—, —CS—O—, —CR⁴R⁵—, —CR⁴R⁵—CR⁶R⁵—, —O—CR⁴R⁵—, —CR⁴R⁵—O—CR⁶R⁷—, —CO—O—CR⁴R⁵—, —O—CO—CR⁴R⁵—, —CR⁴R⁵—O—CO—CR⁶R⁷—, —CR⁴R⁵—CO—O—CR⁶R⁷—, NR⁴—CR⁵R⁶—, or CO—NR⁴—, wherein in the case of a bilaterally asymmetric group on a plane such as —CO—O—, the carbon atom of —CO—O— and G¹ may be bonded or the oxygen atom of —CO—O— and G may be bonded, that is, —CO—O— may be either one of bonding types of -G¹-CO—O— and -G¹-O—CO—, the same shall apply to other groups in this description,

R⁴, R⁵, R⁶, and R⁷ each independently represent a hydrogen atom, a fluorine atom, or an alkyl group having 1 to 4 carbon atoms,

G¹ and G² each independently represent a divalent alicyclic hydrocarbon group having 5 to 8 carbon atoms, the methylene group constituting the alicyclic hydrocarbon group may be optionally substituted with an oxygen atom, a sulfur atom, or —NH—, and the methine group constituting the alicyclic hydrocarbon group may be optionally substituted with a tertiary nitrogen atom, and

L¹ and L² each independently represent a monovalent organic group, and at least one of L¹ and L² has a polymerizable group.

In the polymerizable liquid crystal (A), L¹ is preferably a group represented by the formula (A1), and L² is preferably a group represented by the formula (A2).

P¹-F¹-(B¹-A¹)ₖ-E¹- (A1)

P²-F²-(B²-A²)ₗ-E²- (A2)

In the formula (A1) and the formula (A2),

B¹, B², E¹ and E² each independently represent —CR⁴R⁵—, —CH₂—CH₂—, —O—, —S—, —CO—O—, —O—CO—O—, —CS—O—, —O—CS—O—, —CO—NR¹—, —O—CH₂—, —S—CH₂— or a single bond,

A¹ and A² each independently represent a divalent alicyclic hydrocarbon group having 5 to 8 carbon atoms or a divalent aromatic hydrocarbon group having 6 to 18 carbon atoms, the methylene group constituting the alicyclic hydrocarbon group may be optionally substituted with an oxygen atom, a sulfur atom, or —NH—, the methine group constituting the alicyclic hydrocarbon group may be optionally substituted with a tertiary nitrogen atom,

k and l each independently represent an integer of 0 to 3,

F¹ and F² each independently represent a divalent aliphatic hydrocarbon group having 1 to 12 carbon atoms,

P¹ represents a polymerizable group,

P² represents a hydrogen atom or a polymerizable group, and

R⁴ and R⁵ each independently represent a hydrogen atom, a fluorine atom, or an alkyl group having 1 to 4 carbon atoms.

Preferred examples of the polymerizable liquid crystal (A) include those compounds described in JP-T-2011-207765.

### <Polymerizable Liquid Crystal (B)>

P¹¹-B¹¹-E¹¹-B¹²-A¹¹-B¹³- (X)

In the formula (X), P¹¹ represents a polymerizable group,

A¹¹ represents a divalent alicyclic hydrocarbon group or a divalent aromatic hydrocarbon group, the hydrogen atoms contained in the divalent alicyclic hydrocarbon group and the divalent aromatic hydrocarbon group may be optionally substituted with a halogen atom, an alkyl group having 1 to 6 carbon atoms, an alkoxy group having 1 to 6 carbon atoms, a cyano group or a nitro group, and the hydrogen atoms contained in the alkyl group having 1 to 6 carbon atoms and the alkoxy group having 1 to 6 carbon atoms may be optionally substituted with a fluorine atom,

B¹¹ represents —O—, —S—, —CO—O—, —O—CO—, —O—CO—O—, —CO—NR¹⁶—, —NR¹⁶—CO—, —CO—, —CS—, or a single bond, R¹⁶ represents a hydrogen atom or an alkyl group having 1 to 6 carbon atoms,

B¹² and B¹³ each independently represent —C≡C—, —CH═CH—, —CH₂—CH₂—, —O—, —S—, —CO—, —CO—O—, —O—CO—O—, —CH═N—, —N═N—, —CO—NR¹⁶—, —OCH₂—, —OCF₂—, —CH═CH—CO—O—, or a single bond,

E¹¹ represents an alkanediyl group having 1 to 12 carbon atoms, the hydrogen atom contained in the alkanediyl group may be optionally substituted with an alkoxy group having 1 to 5 carbon atoms, and the hydrogen atom contained in the alkoxy group may be optionally substituted with a halogen atom, and —CH₂— constituting the alkanediyl group may be replaced by —O— or —CO—.

The number of the carbon atoms of the divalent alicyclic hydrocarbon group and the divalent aromatic hydrocarbon group of A¹¹ is preferably in a range of 3 to 18, more preferably in a range of 5 to 12, and particularly preferably 5 or 6. Among them, A¹¹ is preferably a cyclohexane-1,4-diyl group or a 1,4-phenylene group.

E¹¹ is preferably a linear alkanediyl group having 1 to 12 carbon atoms. Examples of E¹¹ include linear alkanediyl groups having 1 to 12 carbon atoms such as a methylene group, an ethylene group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, and a dodecane-1,12-diyl group; and

—CH₂—CH₂—O—CH₂—CH₂—, —CH₂—CH₂—O—CH₂—CH₂—O—CH₂—CH₂— and —CH₂—CH₂—O—CH₂—CH₂—O—CH₂—CH₂—O—CH₂—CH₂—.

B¹¹ is preferably —O—, —S—, or —CO—O—, and more preferably —CO—O—.

B¹² and B¹³ are each independently preferably —O—, —S—, —CO—, —CO—O—, and —O—CO—O—, and more preferably —O— or —O—CO—O—

P¹¹ is preferably a radical polymerizable group or a cationic polymerizable group in terms of particularly high photo-polymerization reactivity. P¹¹ is more preferably either a group represented by the following formulas (P-11) to (P-15) or a p-stilbene group in terms of easiness in handling and easiness in liquid crystal production itself.

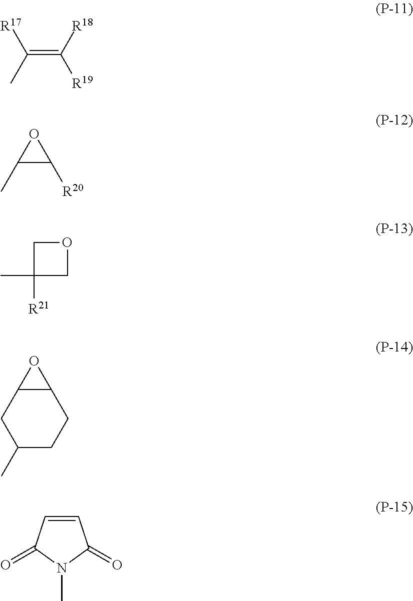

In the formulas (P-11) to (P-15),

R¹⁷ to R²¹ each independently represent an alkyl group having 1 to 6 carbon atoms or a hydrogen atom.

Examples of the group represented by the formulas (P-11) to (P-15) include groups represented by the following formulas (P-16) to (P-20).

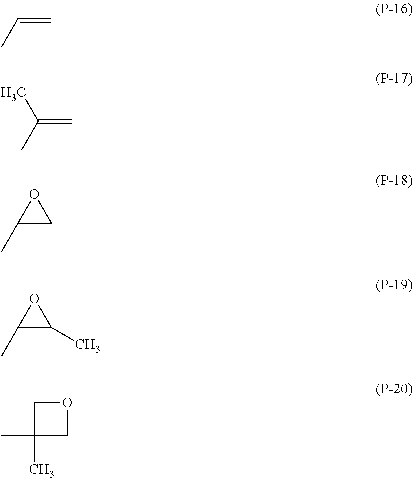

P¹¹ is preferably a group represented by the formulas (P-14) to (P-20) or a p-stilbene group and more preferably a vinyl group, an epoxy group, or an oxetanyl group. Among them, a group represented by P¹¹-B¹¹- is preferably an acryloyloxy group or a methacryloyloxy group.

Examples of the polymerizable liquid crystal (B) represented by the formula (X) include compounds represented by the formula (I), the formula (II), the formula (III), the formula (IV), the formula (V) and the formula (VI).

P¹¹-B¹¹-E¹¹-B¹²-A¹¹-B¹³-A¹²-B¹⁴-A¹³-B¹⁵-A¹⁴-B¹⁶-E¹²-B¹⁷-P¹² (I)

P¹¹-B¹¹-E¹¹-B¹²-A¹¹-B¹³-A¹²-B¹⁴-A¹³-B¹⁵-A¹⁴-F¹¹ (II)

P¹¹-B¹¹-E¹¹-B¹²-A¹¹-B¹³-A¹²-B¹⁴-A¹³-B¹⁵-E¹²-B¹⁷-P¹² (III)

P¹¹-B¹¹-E¹¹-B¹²-A¹¹-B¹³-A¹²-B¹⁴-A¹³-f¹¹ (IV)

P¹¹-B¹¹-E¹¹-B¹²-A¹¹-B¹³-A¹²-B¹⁴-E¹²-B¹⁷-P¹² (V)

P¹¹-B¹¹-E¹¹-B¹²-A¹¹-B¹³-A¹²-F¹¹ (VI)

In the formulas,

A¹² to A¹⁴ each independently have the same meaning of A¹¹ above, B¹⁴ to B¹⁶ each independently have the same meaning of B¹² above, B¹⁷ has the same meaning of B¹¹ above, and E¹² has the same meaning of E¹¹ above,

F¹¹ represents a hydrogen atom, an alkyl group having 1 to 13 carbon atoms, an alkoxy group having 1 to 13 carbon atoms, a cyano group, a nitro group, a trifluoromethyl group, a dimethylamino group, a hydroxy group, a methylol group, a formyl group, a sulfo group (—SO₃H), a carboxyl group, an alkoxycarbonyl group having 1 to 10 carbon atoms, or a halogen atom, and —CH₂— constituting the alkyl group and the alkoxy group may be replaced by —O—, and

P¹² represents the same meaning as P¹¹.

Specific examples of the polymerizable liquid crystal (B) include compounds having a polymerizable group out of the compounds described in “3.8.6 Network (Completely Crosslinked Type)” and “6.5.1 Liquid Crystal Material, b. Polymerizable Nematic Liquid Crystal Material” in “Liquid Crystal Handbook” (edited by Liquid Crystal Handbook Editorial Committee, and published by Maruzen Publishing Co., Ltd. on Oct. 30, 2000); liquid crystal compounds described in JP-A-2010-31223, JP-A-2010-270108, JP-A-2011-6360 and JP-A-2011-207765.

Specific examples of the polymerizable liquid crystal (B) include compounds represented by the following formula (I-1) to formula (1-4), formula (II-1) to formula (11-4), formula (III-1) to formula (III-26), formula (IV-1) to formula (IV-26), formula (V-1) to formula (V-2) and formula (VI-1) to formula (VI-6). k1 and k2 in the following formulas each independently represent an integer of 2 to 12. These polymerizable liquid crystals (B) are preferable in terms of easiness in synthesis thereof and availability.

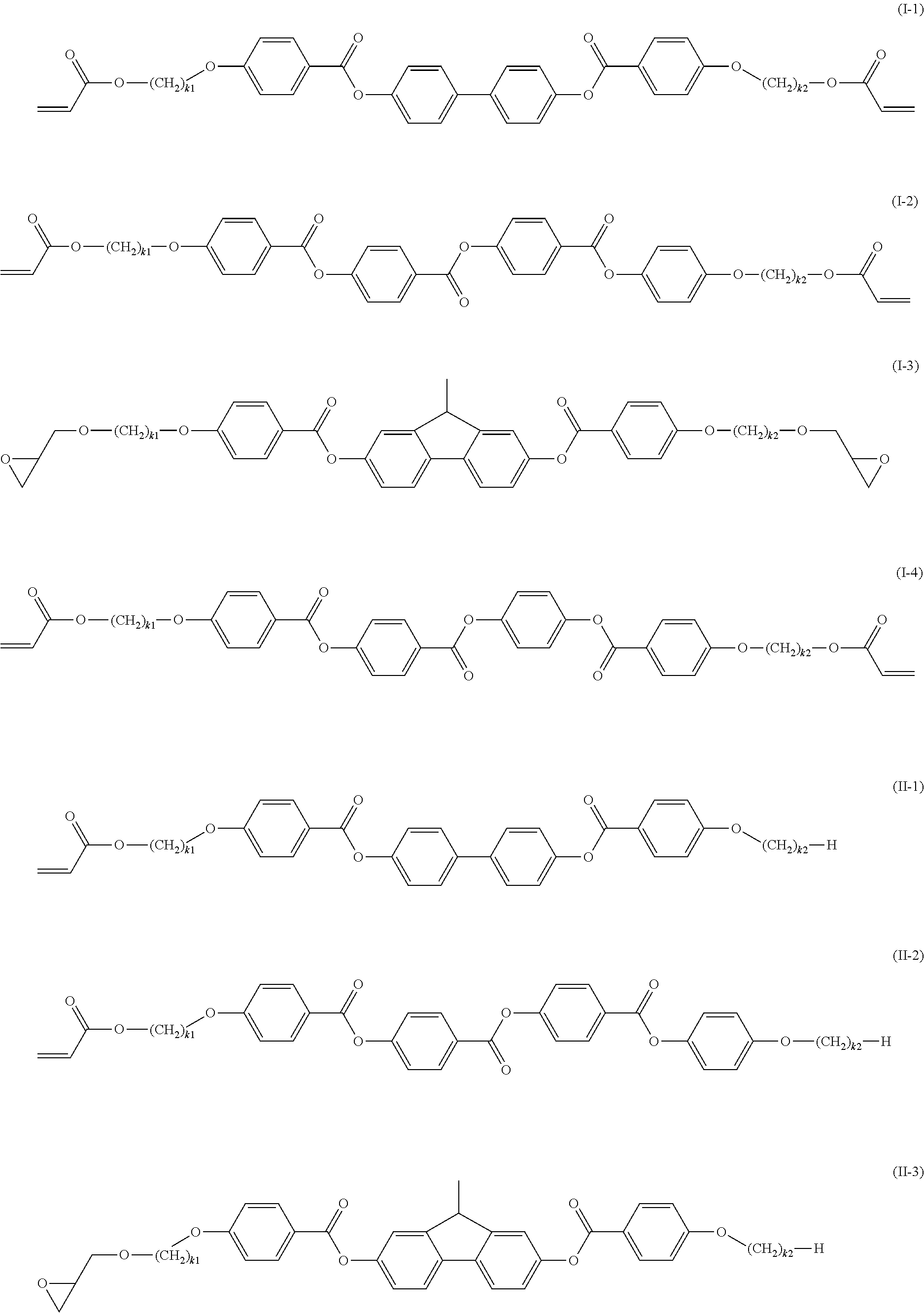

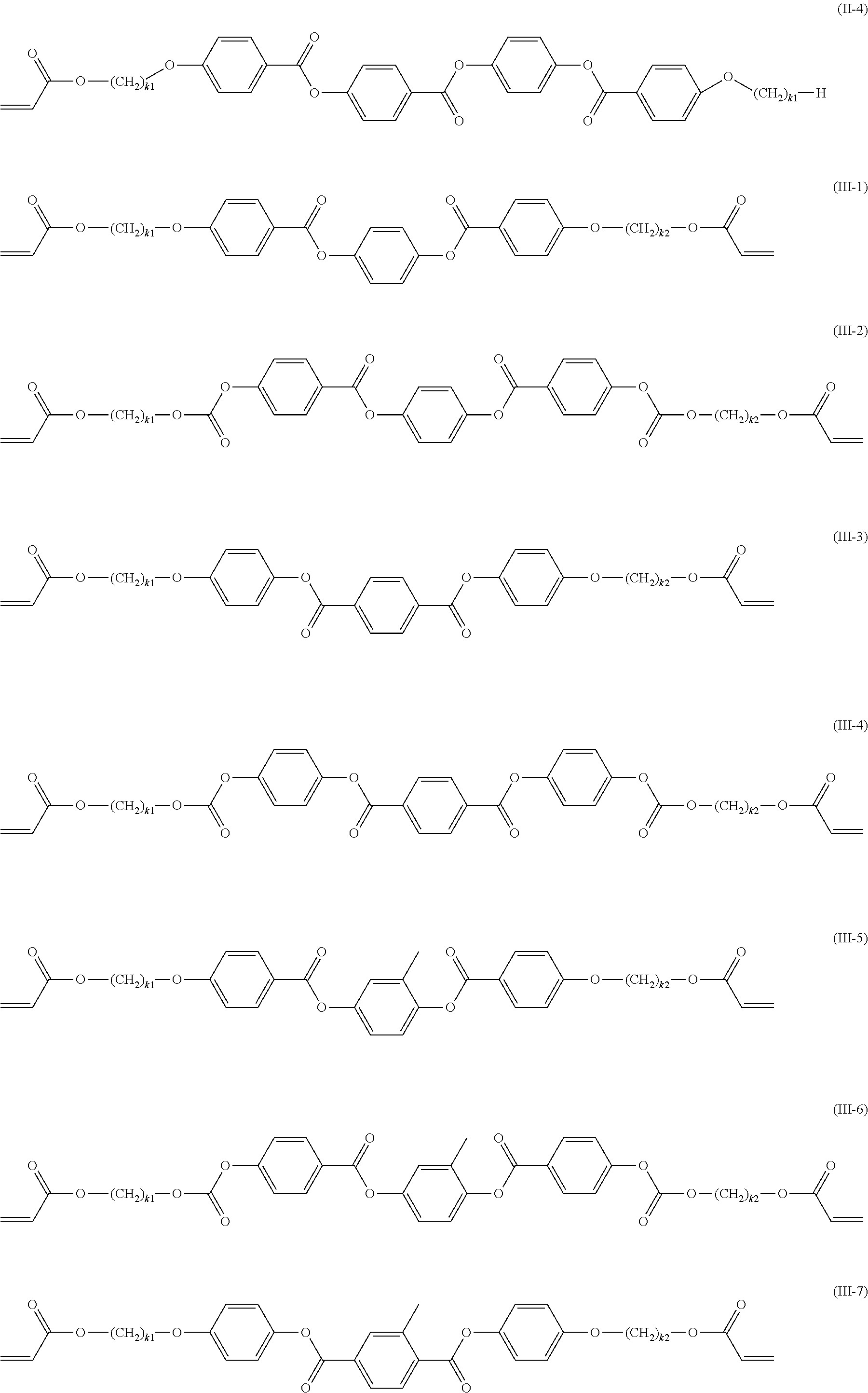

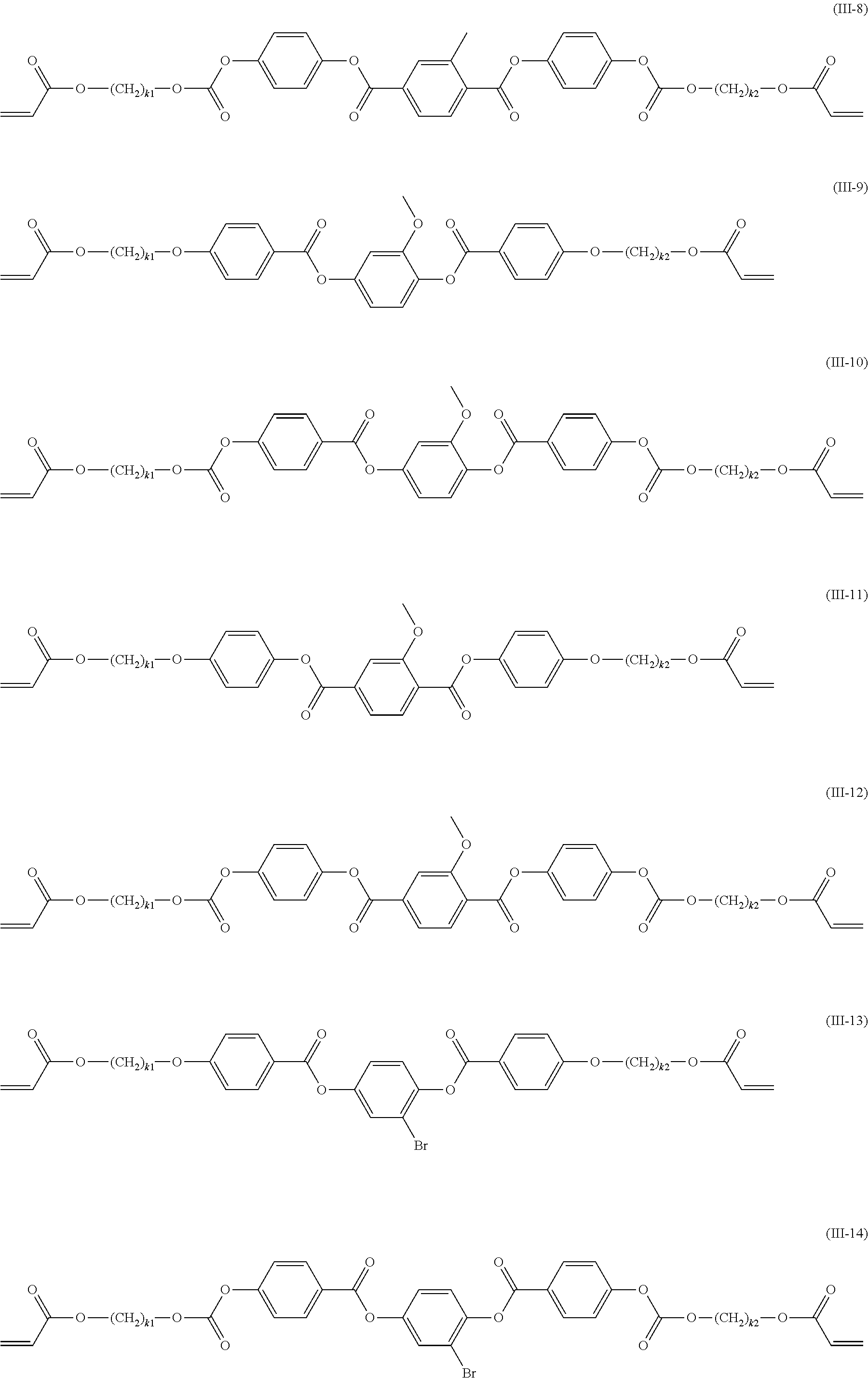

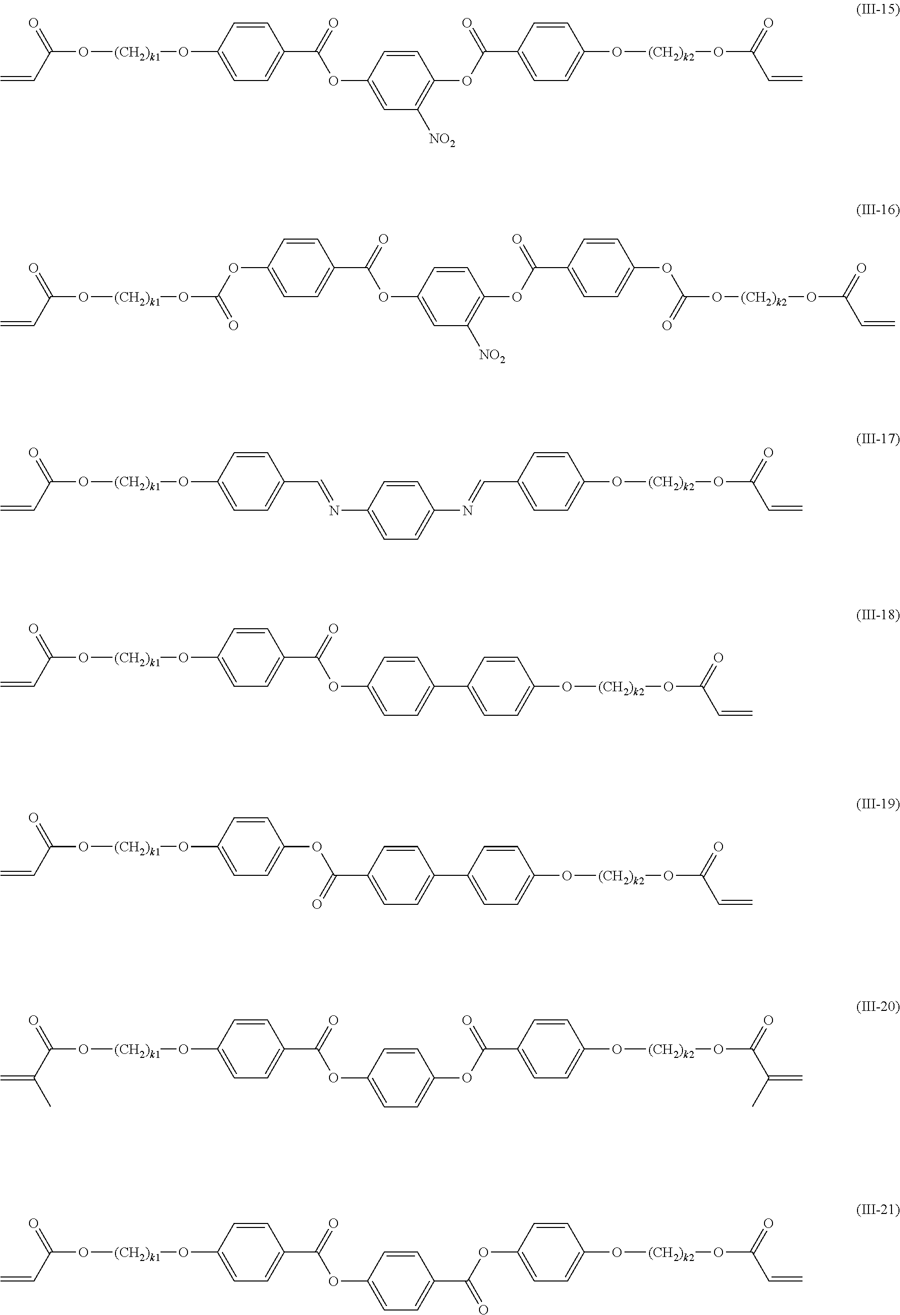

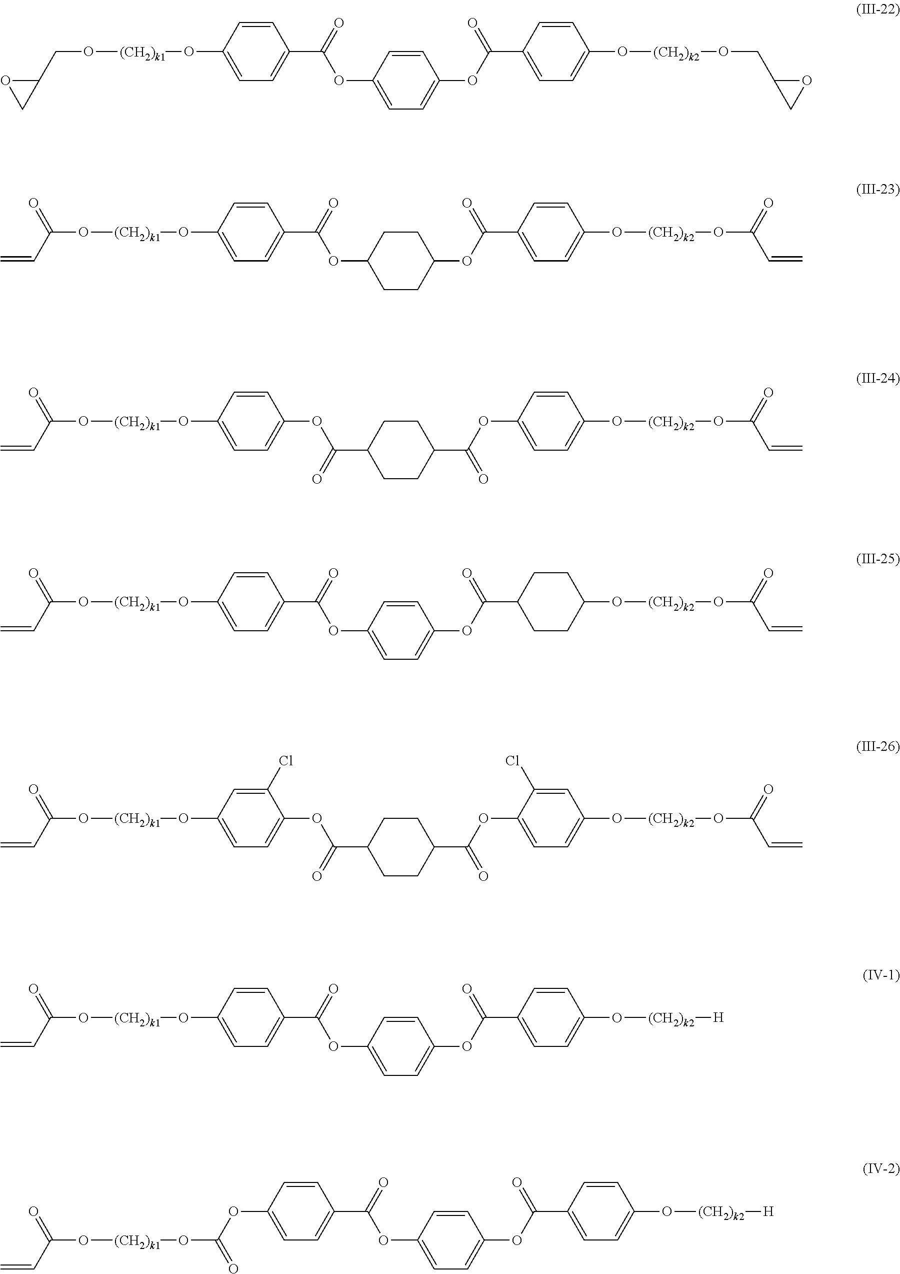

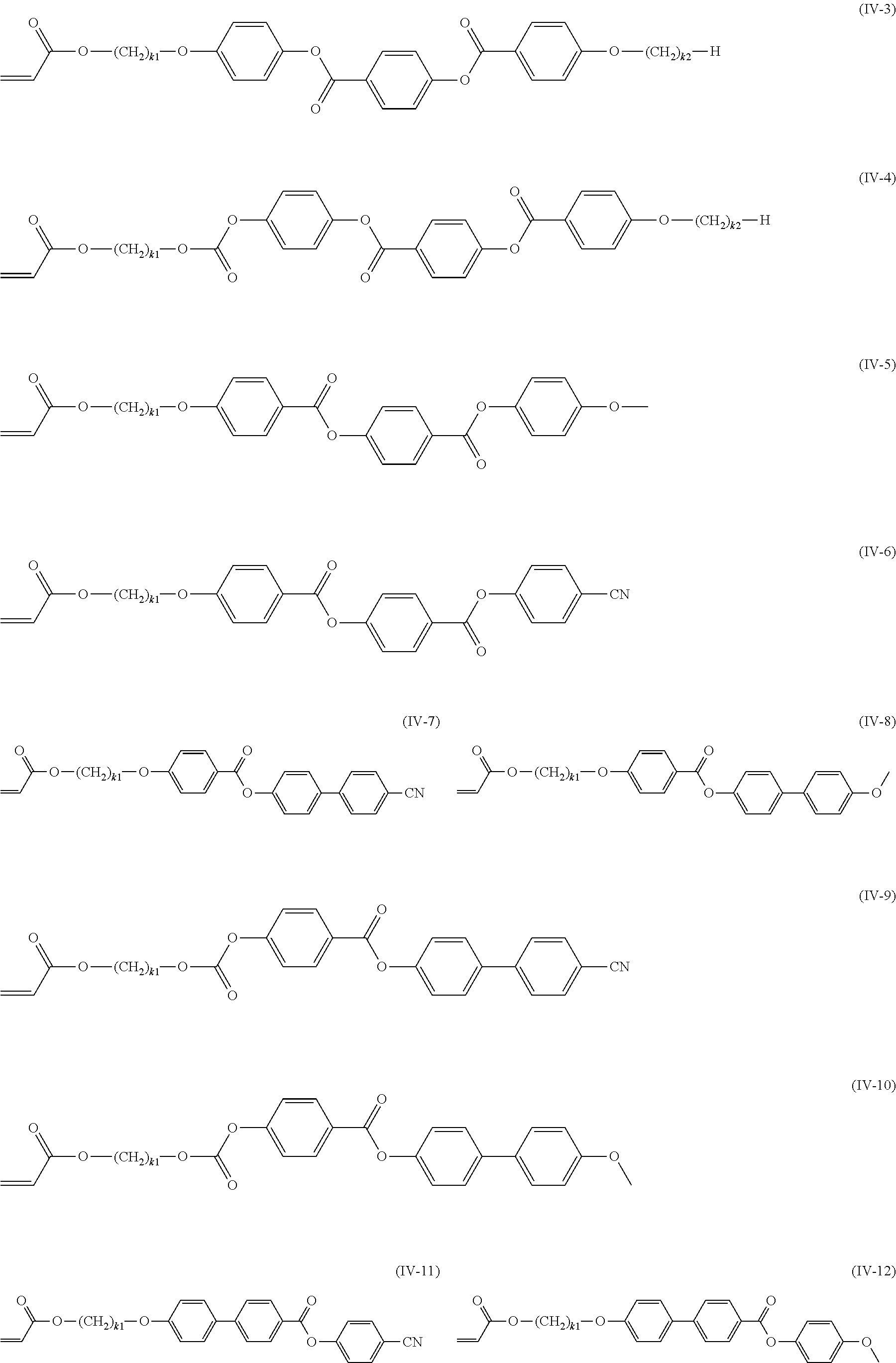

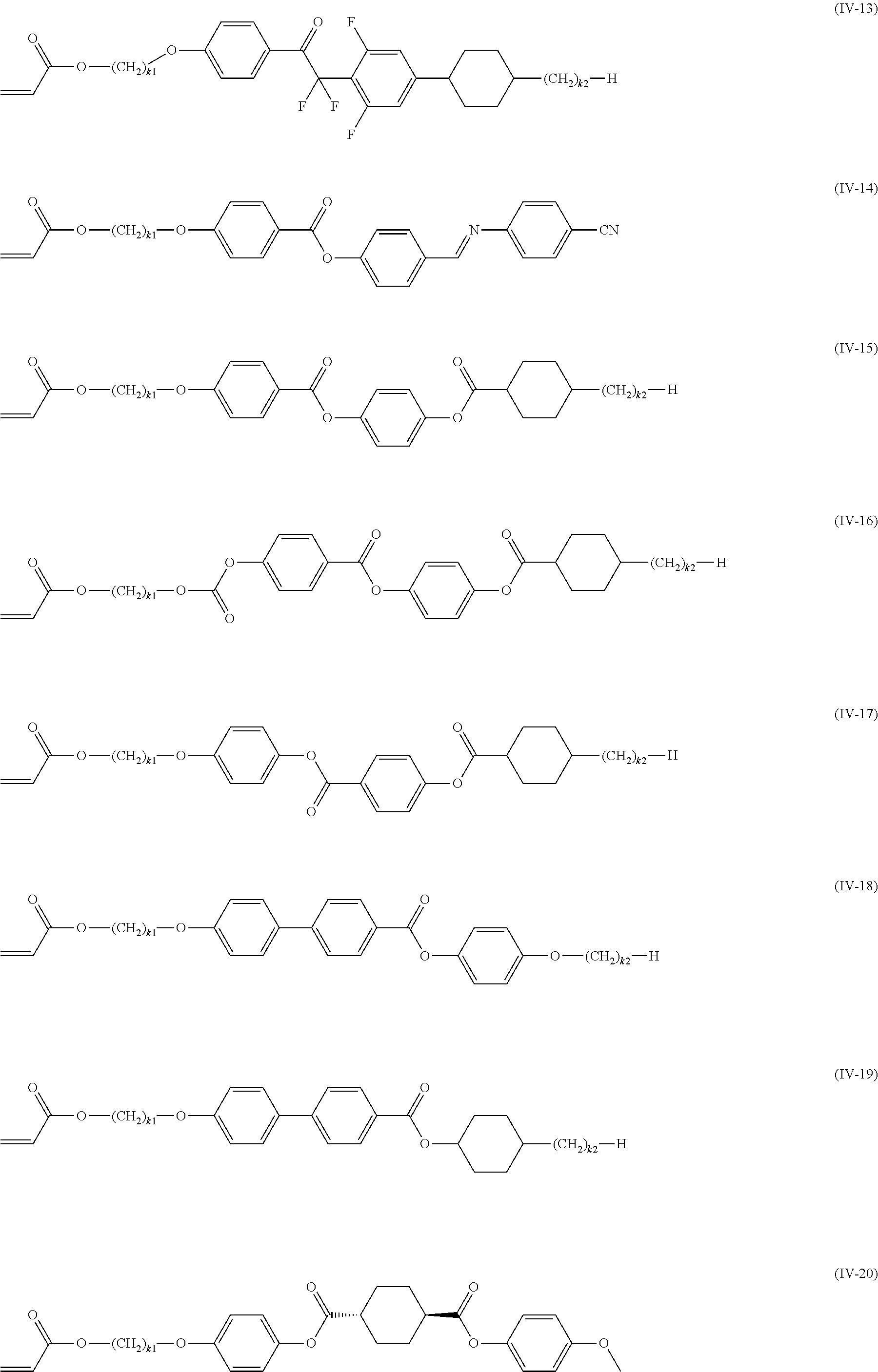

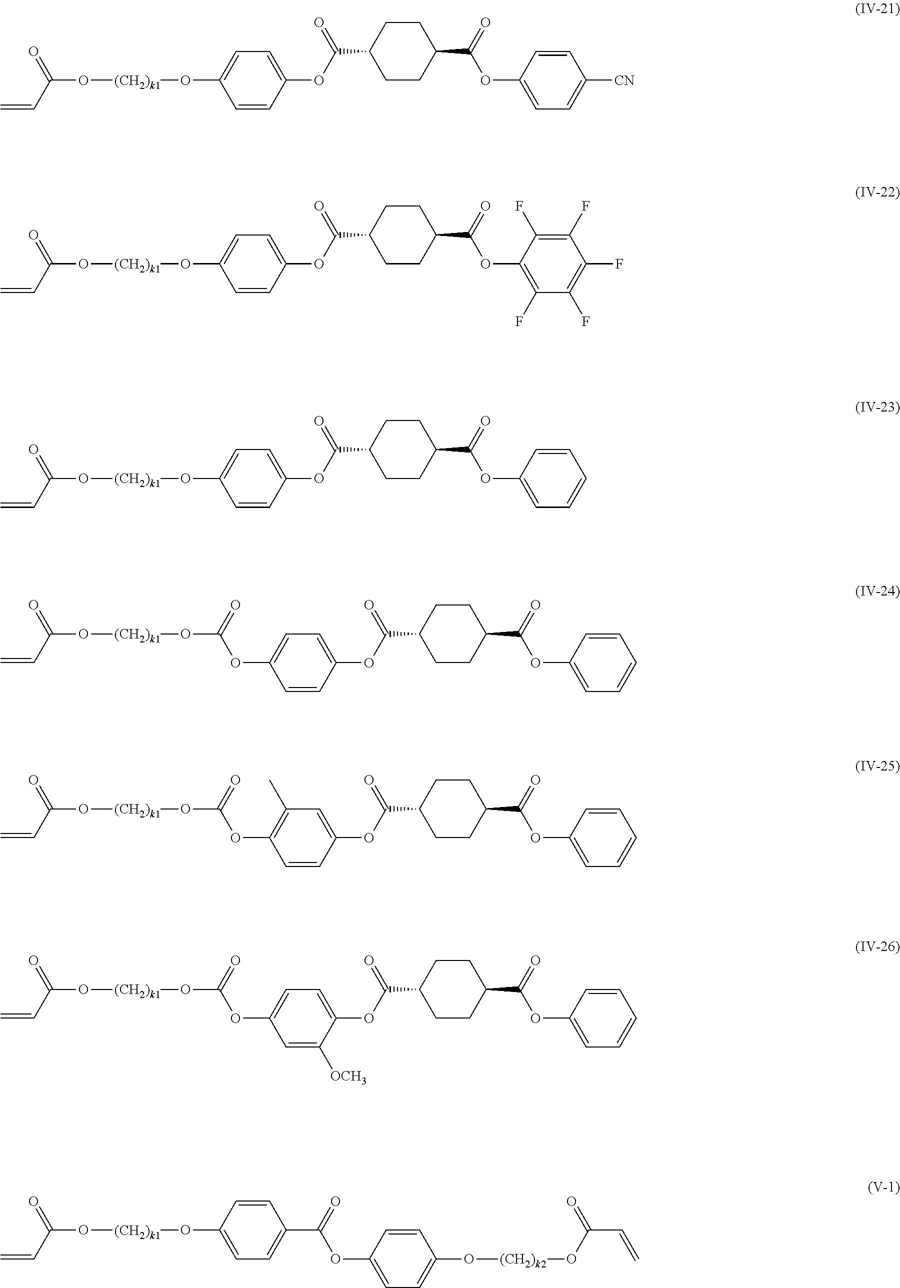

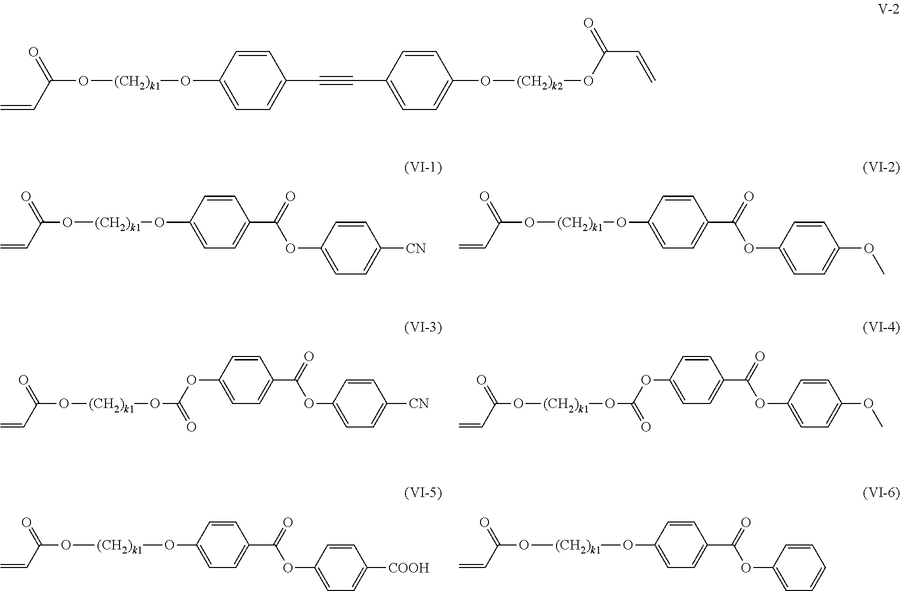

Examples of the disk-shaped polymerizable liquid crystal compound include compounds represented by the formula (W) (hereinafter, may be referred to as polymerizable liquid crystal (C)).

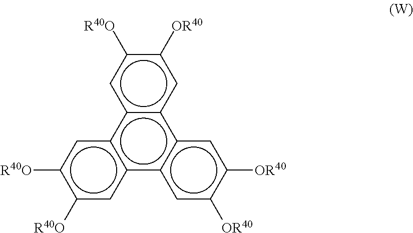

In the formula (W), R⁴⁰ represents the following formulas (W-1) to (W-5).

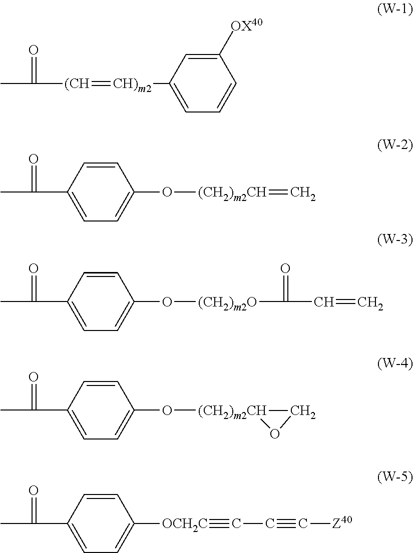

X⁴⁰ and Z⁴⁰ represent an alkanediyl group having 1 to 12 carbon atoms, the hydrogen atom contained in the alkanediyl group may be optionally substituted with an alkoxy group having 1 to 5 carbon atoms, the hydrogen atom contained in the alkoxy group may be optionally substituted with a halogen atom. —CH₂— constituting the alkanediyl group may be replaced by —O— or —CO—.

Specific examples of the polymerizable liquid crystal (C) include compounds described in “6.5.1 Liquid Crystal Material, b. Polymerizable Nematic Liquid Crystal Material, FIG. 6. 21” in “Liquid Crystal Handbook” (edited by Liquid Crystal Handbook Editorial Committee, and published by Maruzen Publishing Co., Ltd. on Oct. 30, 2000); and polymerizable liquid crystal compounds described in JP-A-7-258170, JP-A-7-30637, JP-A-7-309807 and JP-A-8-231470.

### <Polymerizable Liquid Crystal Composition>

The layer (optically anisotropic layer) formed by polymerizing a polymerizable liquid crystal compound can be generally formed by applying a composition containing one or more polymerizable liquid crystal compounds (hereinafter, may be referred to as a polymerizable liquid crystal composition) to an orientation layer and polymerizing the polymerizable liquid crystal compound in the resulting coating film to form a polymer.

The polymerizable liquid crystal composition usually contains a solvent. As the solvent, preferable are solvents which can dissolve the above-mentioned polymerizable liquid crystal compound and which are inert to the polymerization reaction of the above-mentioned polymerizable liquid crystal compound.

Examples of the solvent include alcoholic solvents such as methanol, ethanol, ethylene glycol, isopropyl alcohol, propylene glycol, methyl cellosolve, butyl cellosolve, propylene glycol monomethyl ether and phenol; ester solvents such as ethyl acetate and butyl acetate; ketone solvents such as acetone, methyl ethyl ketone, cyclopentanone, cyclohexanone, cycloheptanone, methyl amyl ketone, methyl isobutyl ketone and N-methyl-2-pyrrolidinone; non-chlorinated aliphatic hydrocarbon solvents such as pentane, hexane and heptane; non-chlorinated aromatic hydrocarbon solvents such as toluene and xylene; nitrile solvents such as acetonitrile; ether solvents such as propylene glycol monomethyl ether, tetrahydrofuran and dimethoxyethane; and chlorinated hydrocarbon solvents such as chloroform and chlorobenzene; etc. These solvents may be used alone or in combination.

The content of the solvent in the polymerizable liquid crystal composition is generally preferably 10 parts by mass to 10000 parts by mass, and more preferably 50 parts by mass to 5000 parts by mass to 100 parts by mass of the solid matter. The solid matter means the total of the components other than the solvent in the polymerizable liquid crystal composition.

The polymerizable liquid crystal composition preferably contains one or more kinds of polymerization initiator. A polymerization initiator is a compound that can start a polymerization reaction of the polymerizable liquid crystal compound. A photopolymerization initiator is preferable in terms of allowing a polymerization reaction to start in low temperature condition. A photopolymerization initiator that can generate an active radical or an acid by the action of light is preferable, and a photopolymerization initiator that generates a radical by the action of light is more preferable.

Examples of the polymerization initiator include benzoin compounds, benzophenone compounds, alkylphenone compounds, acylphosphine oxide compounds, triazine compounds, iodonium salts and sulfonium salts.

Examples of the benzoin compounds include benzoin, benzoin methyl ether, benzoin ethyl ether, benzoin isopropyl ether and benzoin isobutyl ether.

Examples of the benzophenone compounds include benzophenone, methyl o-benzoylbenzoate, 4-phenylbenzophenone, 4-benzoyl-4′-methyldiphenyl sulfide, 3,3′,4,4′-tetra(tert-butylperoxycarbonyl)benzophenone and 2,4,6-trimethylbenzophenone.

Examples of the alkylphenone compounds include diethoxyacetophenone, 2-methyl-2-morpholino-1-(4-methylthiophenyl)propan-1-one, 2-benzyl-2-dimethylamino-1-(4-morpholinophenyl)butan-1-one, 2-hydroxy-2-methyl-1-phenylpropan-1-one, 1,2-diphenyl-2,2-dimethoxyethan-1-one, 2-hydroxy-2-methyl-1-[4-(2-hydroxyethoxy)phenyl]propan-1-one, 1-hydroxycyclohexyl phenyl ketone and an oligomer of 2-hydroxy-2-methyl-1-[4-(1-methylvinyl)phenyl]propan-1-one.

Examples of the acyl phosphine oxide compounds include 2,4,6-trimethylbenzoyldiphenylphosphine oxide and bis(2,4,6-trimethylbenzoyl)phenylphosphine oxide.

Examples of the triazine compounds include 2,4-bis(trichloromethyl)-6-(4-methoxyphenyl)-1,3,5-triazine, 2,4-bis(trichloromethyl)-6-(4-methoxynaphthyl)-1,3,5-triazine, 2,4-bis(trichloromethyl)-6-(4-methoxystyryl)-1,3,5-triazine, 2,4-bis(trichloromethyl)-6-[2-(5-methylfuran-2-yl)ethenyl]-1,3,5-triazine, 2,4-bis(trichloromethyl)-6-[2-(furan-2-yl)ethenyl]-1,3,5-triazine, 2,4-bis(trichloromethyl)-6-[2-(4-diethylamino-2-methylphenyl)ethenyl]-1,3,5-triazine and 2,4-bis(trichloromethyl)-6-[2-(3,4-dimethoxyphenyl)ethenyl]-1,3,5-triazine.

Commercially available polymerization initiators may be used as the polymerization initiator. Examples of the commercially available polymerization initiators include “Irgacure (registered trademark) 907”, “Irgacure (registered trademark) 184”, “Irgacure (registered trademark) 651”, “Irgacure (registered trademark) 819”, “Irgacure (registered trademark) 250” and “Irgacure (registered trademark) 369” (Ciba Japan); “SEIKUOL (registered trademark) BZ”, “SEIKUOL (registered trademark) Z” and “SEIKUOL (registered trademark) BEE” (Seiko Chemical Co., Ltd.); “Kayacure (registered trademark) BP100” (Nippon Kayaku Co., Ltd.); “Kayacure (registered trademark) UVI-6992” (manufactured by The Dow Chemical Company); “Adeka Optomer SP-152” and “Adeka Optomer SP-170” (ADEKA Corporation); “TAZ-A” and “TAZ-PP” (Japan Siebel-Hegner); “TAZ-104” (Sanwa Chemical Co., Ltd.); etc.

When the polymerizable liquid crystal composition contains a polymerization initiator, the content of the polymerization initiator may be adjusted properly depending on the kind and amount of the polymerizable liquid crystal compound contained in the composition, but the content is preferably 0.1 to 30 parts by mass, more preferably 0.5 to 10 parts by mass, and furthermore preferably 0.5 to 8 parts by mass to 100 parts by mass of the polymerizable liquid crystal compound. If the content of the polymerization initiator falls within the above range, the polymerization can be preferably carried out without disturbance of the orientation of the polymerizable liquid crystal compound.

When the polymerizable liquid crystal composition contains a photopolymerization inhibitor, the composition may further contain a photosensitizer. Examples of the photosensitizer include xanthone compounds such as xanthone and thioxanthone (e.g., 2,4-diethylthioxanthone and 2-isopropylthioxanthone); anthracene compounds such as anthracene and alkoxy group-containing anthracenes (e.g., dibutoxyanthracene); phenothiazine, rubrene, etc.

When the polymerizable liquid crystal composition contains a photopolymerization inhibitor and a photosensitizer, the polymerization reaction of the polymerizable liquid crystal compound contained in the composition can be further promoted. The use amount of the photosensitizer may be adjusted properly depending on the kinds of the photopolymerization initiator and the polymerizable liquid crystal compound, but the use amount is preferably 0.1 to 30 parts by mass, more preferably 0.5 to 10 parts by mass, and furthermore preferably 0.5 to 8 parts by mass to 100 parts by mass of the polymerizable liquid crystal compound.

The polymerizable liquid crystal composition may contain a reactive additive. As the reactive additive, preferable are those having a carbon-carbon unsaturated bond and an active hydrogen reactive group in the molecule. “Active hydrogen reactive group” as used herein means a group having reactivity to a group having active hydrogen such as a carboxyl group (—COOH), a hydroxyl group (—OH) or an amino group (—NH₂). Typical examples thereof are a glycidyl group, an oxazoline group, a carbodiimide group, an aziridine group, an imide group, an isocyanate group, a thioisocyanate group and a maleic anhydride group. The number of the carbon-carbon unsaturated bond and the active hydrogen reactive group included in the molecule of the reactive additive is usually 1 to 20, and preferably 1 to 10, respectively.

In the reactive additive, it is preferable that at least two active hydrogen reactive groups exist in the molecule. In this case, a plurality of the active hydrogen reactive groups may be same as or different from each other.

The carbon-carbon unsaturated bond included in the molecule of the reactive additive means a carbon-carbon double bond or a carbon-carbon triple bond, and a carbon-carbon double bond is preferable. Among them, the reactive additive preferably contains a carbon-carbon unsaturated bond as a vinyl group and/or a (meth)acrylic group in the molecule. Further, the active hydrogen reactive group is preferably at least one kind selected from the group consisting of an epoxy group, a glycidyl group and an isocyanate group. A reactive additive having an acrylic group as the carbon-carbon double bond and an isocyanate group as the active hydrogen reactive group is particularly preferable.

Examples of the reactive additive include compounds having a (meth)acrylic group and an epoxy group such as methacryloxy glycidyl ether and acryloxy glycidyl ether; compounds having a (meth)acrylic group and an oxetane group such as oxetane acrylate and oxetane methacrylate; compounds having a (meth)acrylic group and a lactone group such as lactone acrylate and lactone methacrylate; compounds having a vinyl group and an oxazoline group such as vinyloxazoline and isopropenyloxazoline; compounds having a (meth)acrylic group and an isocyanate group such as isocyanatomethyl acrylate, isocyanatomethyl methacrylate, 2-isocyanatoethyl acrylate and 2-isocyanatoethyl methacrylate; and oligomers of these monomers. Further, examples thereof include compounds having a vinyl group or vinylene group and an acid anhydride such as methacrylic anhydride, acrylic anhydride, maleic anhydride and vinyl maleic anhydride; etc. Among them, particularly preferable are methacryloxy glycidyl ether, acryloxy glycidyl ether, isocyanatomethyl acrylate, isocyanatomethyl methacrylate, vinyloxazoline, 2-isocyanatoethyl acrylate, 2-isocyanatoethyl methacrylate, and their monomers and oligomers, and isocyanatomethyl acrylate, 2-isocyanatoethyl acrylate, and oligomers of these monomers.

The reactive additive is preferably a compound represented by the following formula (Y).

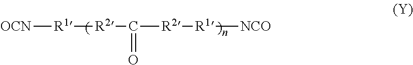

In the formula (Y),

n represents an integer of 1 to 10, R^{1′} represents a divalent aliphatic or alicyclic hydrocarbon group having 2 to 20 carbon atoms or a divalent aromatic hydrocarbon group having 5 to 20 carbon atoms, one of two R²'s in each repeating unit is —NH— and the other is a group represented by ═N—C(═O)—R^{3′}, R^{3′} represents a hydroxyl group or a group having a carbon-carbon unsaturated bond,

when n is 2 or more, at least one R^{3′} of a plurality of ═N—C(═O)—R^{3′} groups is a group having a carbon-carbon unsaturated bond.

Among the reactive additives represented by the above-mentioned formula (Y), particularly preferable are compounds represented by the following formula (YY) (hereinafter, may be referred to as compound (YY)). n has the same meaning as that defined in the formula (Y).

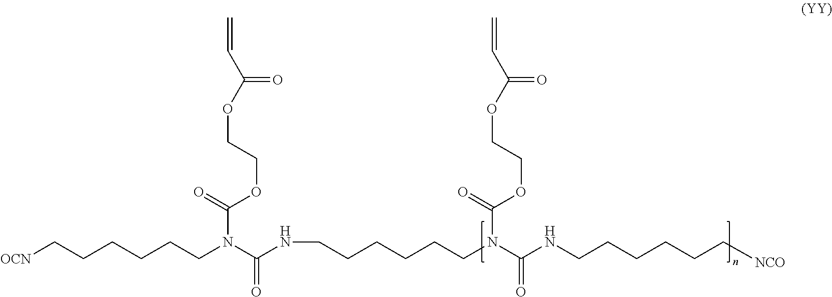

As the compound (YY), commercially available products may be used as they are, or after being purified if necessary. Examples of the commercially available products include Laromer (registered trademark) LR-9000 (manufactured by BASF).

When the polymerizable liquid crystal composition contains a reactive additive, the content of the reactive additive is usually not less than 0.1 parts by mass and not more than 30 parts by mass, and preferably not less than 0.1 parts by mass and not more than 5 parts by mass to 100 parts by mass of the polymerizable liquid crystal compound.

The polymerizable liquid crystal composition preferably contains one or more kinds of leveling agents. A leveling agent has a function of adjusting the fluidity of the polymerizable liquid crystal composition and making the coating film flat which is obtained by applying the polymerizable liquid crystal composition. A specific example thereof include a surfactant. Examples of the leveling agent include those which are the same as the leveling agent contained in the following orientation layer.

When the polymerizable liquid crystal composition contains a leveling agent, the content of the leveling agent is preferably not less than 0.01 parts by mass and not more than 5 parts by mass, more preferably not less than 0.05 parts by mass and not more than 5 parts by mass, and furthermore preferably not less than 0.05 parts by mass and not more than 3 parts by mass to 100 parts by mass of the polymerizable liquid crystal compound. In terms of formation of an optically anisotropic layer with smoothness and no unevenness and also of easiness in orientation of the polymerizable liquid crystal compound in the optically anisotropic layer, the content of the leveling agent is preferably not less than 0.001 parts by mass and not more than 5 parts by mass.

In order to more stably advance the polymerization reaction of the polymerizable liquid crystal compound, the polymerizable liquid crystal composition may contain a proper amount of a polymerization inhibitor, and the polymerization inhibitor makes it easy to control the degree of advancement in the polymerization reaction of the polymerizable liquid crystal compound.

Examples of the polymerization inhibitor include radical scavengers such as hydroquinone, alkoxy group-containing hydroquinone, alkoxy group-containing catechol (e.g., butylcatechol), pyrogallol, 2,2,6,6-tetramethyl-1-piperidinyloxyradical; thiophenols; β-naphthylamines; and β-naphthols; etc.

When the polymerizable liquid crystal composition contains a polymerization inhibitor, the content of the polymerization inhibitor may be properly adjusted depending on the kind and amount of the polymerizable liquid crystal compound as well as the use amount of the photosensitizer. The content of the polymerization inhibitor is preferably 0.1 to 30 parts by mass, more preferably 0.5 to 10 parts by mass, and further preferably 0.5 to 8 parts by mass to 100 parts by mass of the polymerizable liquid crystal compound. If the content of the polymerization inhibitor falls within the above range, the polymerizable liquid crystal compound can be polymerized without disturbance of the orientation of the polymerizable liquid crystal compound.

The polymerizable liquid crystal composition is applied by a known method, for example, a coating method such as a spin coating method, an extrusion method, a gravure coating method, a die coating method, a slit coating method, a bar coating method or an applicator method, or a printing method such as flexography. After the application, the solvent is usually removed under the condition that the polymerizable liquid crystal compound contained in the resulting coating film is not polymerized to form a dry coating. Examples of the drying method include a natural drying method, a ventilation drying method, heat drying and a reduced-pressure drying method.

The liquid crystal orientation of the polymerizable liquid crystal compound is controlled in accordance with the characteristics of the orientation layer and the polymerizable liquid crystal compound. For example, if the orientation layer is made of a material that exhibits horizontal orientation regulation force as the orientation regulation force, the polymerizable liquid crystal compound can attain horizontal orientation or hybrid orientation. If the orientation layer is made of a material that exhibits perpendicular orientation regulation force, the polymerizable liquid crystal compound can attain perpendicular orientation or oblique orientation.

When the orientation layer is made of an orienting polymer, the orientation regulation force can be arbitrarily adjusted depending on the surface state or rubbing conditions, and when the orientation layer is made of a photo-orienting polymer, the orientation regulation force can be arbitrarily adjusted depending on polarizing irradiation conditions, etc. The liquid crystal orientation can be controlled by selecting the physical properties of the polymerizable liquid crystal compound such as surface tension and liquid crystallinity.

The polymerization of the polymerizable liquid crystal compound can be carried out by a known method for polymerizing a compound having a polymerizable functional group. Specific examples of the method include heat polymerization and photopolymerization, and in terms of easiness in polymerization, photopolymerization is preferable. When the polymerizable liquid crystal compound is polymerized by photopolymerization, it is preferable that the polymerizable liquid crystal compound in the dry coating formed by applying a polymerizable liquid crystal composition containing a photopolymerization initiator in accordance with the above-mentioned method and drying the polymerizable liquid crystal composition is put in a state where the polymerizable liquid crystal compound exhibits a liquid crystal phase, and thereafter, photopolymerization is carried out while the liquid crystal state is held.

The photopolymerization is carried out by irradiating the dry coating with light. The light to be irradiated is properly selected depending on the kind of the photopolymerization initiator contained in the dry coating, and the kind and amount of the polymerizable liquid crystal compound (particularly, the kind of the photopolymerizable group which the polymerizable liquid crystal compound has). Specific examples of the light include visible light, ultraviolet light and active electron beam. Among them, ultraviolet light is preferable in terms of easiness in control of the advancement of the polymerization reaction and usability of an apparatus employed widely in the art as a photopolymerization apparatus. It is preferable to select the kinds of the polymerizable liquid crystal compound and the photopolymerization initiator so as to make photopolymerization possible by ultraviolet light. Further, irradiation with light while the dry coating is cooled with a proper cooling means also makes it possible to control the polymerization temperature. The use of such a cooling means can properly form an optically anisotropic layer even if a substrate has relatively low heat resistance when the polymerization of the polymerizable liquid crystal compound is carried out at a lower temperature. At the time of photopolymerization, a patterned optically anisotropic layer can also be obtained by carrying out masking or development.

### <Stretched Film>

A stretched film is usually obtained by stretching a substrate. A method for stretching a substrate includes preparing a roll (wound body) on which a substrate is wound, continuously unwinding the substrate from the wound body, and transporting the unwound substrate to a heating furnace. The setting temperature in the heating furnace is preferably not lower than about the glass transition temperature (unit: ° C.) of the substrate and not higher than (glass transition temperature+100° C.), and more preferably not less than about the glass transition temperature and not more than (glass transition temperature+50° C.). In the heating furnace, when the substrate is stretched in the advancement direction or in the direction orthogonal to the advancement direction, a uniaxial or biaxial heat stretching treatment may be carried out while the transporting direction or the tensile force are adjusted and the substrate is inclined at an arbitrarily angle. The magnification of the stretching is usually 1.1 to 6 times and preferably 1.1 to 3.5 times. A method for stretching in an oblique direction is not particularly limited if it is a method which can continuously slant the orientation axis at a desired angle, and conventionally known stretching methods can be employed. Examples of the stretching methods include the methods described in JP-A-S50-83482 and JP-A-H02-113920. When the stretching gives a retardation property to the film, the thickness after the stretching is determined depending on the thickness before the stretching or the stretching magnification.

The in-plane retardation value of the stretched film and the retardation value in the thickness direction can be adjusted in accordance with Δn(λ) and the film thickness d, similarly to the layer formed by polymerizing a polymerizable liquid crystal compound.

Examples of a stretched film obtained by stretching a polymer film having a specified structure and having optical characteristics defined by the formula (1) and the formula (2) above include commercially available stretched films made of polycarbonate-based resins, and specific examples thereof include “PURE-ACE (registered trademark) WR” (manufactured by Teijin Ltd.).

The above-mentioned substrate is usually a transparent substrate. A transparent substrate means a substrate having transparency which can transmit light, particularly visible light, and transparency is a characteristic such that the transmittance of light with a wavelength of 380 to 780 nm is not less than 80%. Examples of the transparent substrate include translucent resin substrates. Examples of the resin constituting translucent resin substrates include polyolefins such as polyethylene and polypropylene; cyclic olefin-based resins such as norbornene type polymers; polyvinyl alcohol; polyethylene terephthalate; polymethacrylic acid ester; polyacrylic acid ester; cellulose esters such as triacetyl cellulose, diacetyl cellulose and cellulose acetate propionate; polyethylene naphthalate; polycarbonate; polysulfone; polyether sulfone; polyether ketone; polyphenylene sulfides; and polyphenylene oxides. In terms of availability and transparency, polyethylene terephthalate, polymethacrylic acid ester, cellulose ester, cyclic olefin-based resin, or polycarbonate is preferable.

A cellulose ester is one in which some or all of hydroxyl groups contained in cellulose are esterified and is commercially available. A cellulose ester substrate is also commercially available. Examples of the commercially available cellulose ester substrate include “FUJITAC (registered trademark) Film” (Fuji Film Corporation); “KC8UX2M”, “KC8UY” and “KC4UY” (Konica Minolta Opto)

A polymethacrylic acid ester and a polyacrylic acid ester are commercially available in an easy manner. Hereinafter, a polymethacrylic acid ester and a polyacrylic acid ester may be collectively referred to as (meth)acrylic resins.

Examples of the (meth)acrylic resins include homopolymers of methacrylic acid alkyl esters and acrylic acid alkyl esters and copolymers of methacrylic acid alkyl esters and acrylic acid alkyl esters. Examples of the methacrylic acid alkyl esters include methyl methacrylate, ethyl methacrylate and propyl methacrylate, and examples of the acrylic acid alkyl esters include methyl acrylate, ethyl acrylate and propyl acrylate. As such (meth)acrylic resins, those commercially available as (meth)acrylic resins for general use can be used. As such (meth)acrylic resins, those referred to as impact-resistant (meth)acrylic resins may be used. Examples of the commercially available (meth)acrylic resins include “HT55X” and “TECHNOLOY S001” available from Sumitomo Chemical Co., Ltd. “TECHNOLOY S001” is available in the form of a film.

Cyclic olefin-based resins are commercially available in an easy manner. Examples of the commercially available cyclic olefin-based resins include “Topas” (registered trademark) (Ticona (Germany)), “Arton” (registered trademark) (JSR Co., Ltd.), “ZEONOR” (registered trademark) (ZEON CORPORATION), “ZEONEX” (registered trademark) (ZEON CORPORATION) and “Apel” (registered trademark) (Mitsui Chemicals, Inc.). Such a cyclic olefin-based resin is formed into a film by a known means such as a solvent casting method or a melt extrusion method to give a substrate. Commercially available cyclic olefin-based resin substrates are also usable. Examples of the commercially available cyclic olefin-based resin substrates include “Escena” (registered trademark) (Sekisui Chemical Co., Ltd.), “SCA40” (registered trademark) (Sekisui Chemical Co., Ltd.), “ZEONOR Film” (registered trademark) (Optes Inc.) and “Arton Film” (registered trademark) (JSR Co., Ltd.).

When the cyclic olefin-based resin is a copolymer of a cyclic olefin with a linear olefin or an aromatic compound having a vinyl group, the content ratio of the structural unit derived from the cyclic olefin is usually not more than 50 mol % and preferably in a range of 15 to 50 mol % to the entire structure units of the copolymer. Examples of the linear olefin include ethylene and propylene, and examples of the aromatic compound having a vinyl group include styrene, α-methylstyrene and alkyl-substituted styrene. When the cyclic olefin-based resin is a tertiary copolymer of a cyclic olefin, a linear olefin and an aromatic compound having a vinyl group, the content ratio of the structural unit derived from the linear olefin is usually 5 to 80 mol % to the entire structure units of the copolymer, and the content ratio of the structural unit derived from the aromatic compound having a vinyl group is usually 5 to 80 mol % to the entire structure units of the copolymer. Such a tertiary copolymer has an advantage that the use amount of a cyclic olefin with high cost can be relatively small in its production.

An optically anisotropic layer formed from the above-mentioned polymerizable liquid crystal compound or stretched film preferably has optical characteristics defined by the following formula (1) and the formula (2):

Re(450)/Re(550)≦1.00 (1)

1.00≦Re(650)/Re(550) (2)

wherein, Re (λ) represents an in-plane retardation value to light with a wavelength of, nm.

The optically anisotropic layer having optical characteristics defined by the formula (1) and the formula (2) can be obtained in the case where a polymerizable liquid crystal compound having a specified structure is polymerized, or in the case where a polymer film having a specified structure is stretched, or in the case where a layer having optical characteristics defined by the following formulas (4), (6) and (7) and a layer having optical characteristics defined by the following formulas (5), (6) and (7) are combined while a specified slow axis relation is satisfied:

Re(450)/Re(550)≦1.00 (1)

1.00≦Re(650)/Re(550) (2)

100 nm<Re(550)<160 nm (4)

200 nm<Re(550)<320 nm (5)

Re(450)/Re(550)≧1.00 (6)

1.00≧Re(650)/Re(550) (7)

wherein, Re(550) represent an in-plane retardation value at a wavelength of 550 nm. Re(λ) represents an in-plane retardation value to light with a wavelength of λ nm.

When the optically anisotropic layer has optical characteristics defined by the formula (1) and the formula (2), the present optical film having optical characteristics defined by the formula (1) and the formula (2) can be obtained. Uniform polarization conversion characteristics to light with each wavelength in a visible light range can be obtained and light leakage at the time of black display of a display device such as an organic EL display device can be suppressed, so that the present optical film is preferable to have optical characteristics defined by the formula (1) and the formula (2).

Examples of the polymerizable liquid crystal compound having a specified structure include the polymerizable liquid crystal (A). When the orientation of the polymerizable liquid crystal (A) is set in such a manner that the optical axis can be horizontal to the substrate flat plane, an optically anisotropic layer having optical characteristics defined by the formula (1) and the formula (2) can be obtained. Further, when the film thickness is adjusted in accordance with the formula (10), an optically anisotropic layer having the desired in-plane retardation value such as an optical characteristic defined by the formula (4) can be obtained.

Examples of the method for combining the layer A having optical characteristics defined by the formulas (4), (6) and (7) and the layer B having optical characteristics defined by the formulas (5), (6) and (7) while a specified slow axis relation is satisfied include well-known methods.

For example, JP-A-2001-4837, JP-A-2001-21720 and JP-A-2000-206331 disclose a retardation film having at least two optically anisotropic layers containing liquid crystal compound. Additionally, the two optically anisotropic layers may be composed of a polymer film as one layer and an optically anisotropic layer containing a liquid crystal compound as the other layer.

The optically anisotropic layer having optical characteristics defined by the formula (6) and the formula (7) can be obtained by well-known methods. That is, an optically anisotropic layer obtained by a method other than the method for obtaining the optically anisotropic layer having optical characteristics defined by the formula (1) and the formula (2) generally has optical characteristics defined by the formula (6) and the formula (7).

When the optically anisotropic layer has a stretched film, the thickness of the optically anisotropic layer is usually not more than 300 μm, preferably not less than 5 μm and not more than 100 μm, and more preferably not less than 10 m and not more than 50 μm. When the optically anisotropic layer is a layer formed by polymerizing a polymerizable liquid crystal compound, the thickness of the optically anisotropic layer is usually not more than 20 μm, preferably not more than 5 μm, and more preferably not less than 0.5 μm and not more than 3 μm. The thickness of the optically anisotropic layer can be measured by measurement with an interference thickness meter, a laser microscope, or a contact-type thickness meter.

### [Substrate]

The optical film of the present invention may have a substrate, and in this case, an orientation layer is formed on the substrate. Examples of the substrate include those described above, but preferable is a substrate with low retardation. Examples of the substrate with low retardation include unstretched cyclic olefin-based resin substrates and cellulose ester films having no retardation such as ZEROTAC (registered trademark) (Konica Minolta Opto) and Z-TAC (Fujifilm Corporation).

Before the formation of an orientation layer, the surface of the substrate on which the orientation layer is formed may be subjected to a surface treatment. Examples of the method for the surface treatment include a method of treating the surface of the substrate with corona or plasma in a vacuum or an atmospheric pressure; a method of treating the surface of the substrate with a laser; a method of treating the surface of the substrate with ozone; a method of subjecting the surface of the substrate to a saponifying treatment or a method of subjecting the surface of the substrate to a flame treatment; a method of coating the surface of the substrate with a coupling agent to be subjected to a primer treatment; and a graft-polymerization method of causing a reactive monomer or a polymer having reactivity to adhere onto the surface of the substrate, and then irradiating the monomer or polymer with radial rays, plasma or ultraviolet rays to cause a reaction of the monomer or polymer. Among them, preferable is the method of treating the surface of the substrate with corona or plasma in a vacuum or an atmospheric pressure.

Examples of the method of treating the surface of the substrate with corona or plasma include a method of setting the substrate between opposed electrodes under a pressure close to the atmospheric pressure, and then generating corona or plasma to treat the surface of the substrate therewith; a method of causing a gas to flow into the gap between opposed electrodes, making the gas into plasma between the electrodes, and blowing the plasma-state gas onto the substrate; and a method of generating glow discharge plasma under a low pressure to treat the surface of the substrate therewith.

Among them, preferable is the method of setting the substrate between opposed electrodes under a pressure close to the atmospheric pressure, and then generating corona or plasma to treat the surface of the substrate therewith, or the method of causing a gas to flow into the gap between opposed electrodes, making the gas into plasma between the electrodes, and blowing the plasma-state gas onto the substrate. Usually, these surface treatments with corona or plasma can be carried out in a commercially available surface treatment apparatus.

The surface of the substrate on which no orientation layer is formed may be subjected to a hard coat treatment, an antistatic treatment, or the like. The substrate may contain an additive such as an ultraviolet absorbent to such an extent that performance is not affected.

The thickness of the substrate is usually not less than 5 μm and not more than 300 μm, and preferably not less than 10 μm and not more than 200 μm, because if the thickness is too thin, strength is lowered and processability tends to be deteriorated.

### [Orientation Layer]

The orientation layer in the present invention has an orientation regulation force for executing liquid crystal orientation of a polymerizable liquid crystal compound in a desired direction, and is characterized by containing a leveling agent. The inventors of the present invention have found that addition of a leveling agent to an orientation layer unexpectedly improves an optically compensating characteristic.

A leveling agent functions to adjust the fluidity of an orienting material and to make a coating layer flatter which is obtained by applying a composition for forming an orientation layer. Specific examples of the leveling agent include surfactants, and these surfactants have an effect to lower the surface tension of the coating layer. The leveling agent is preferably at least one kind selected from the group consisting of leveling agents containing a polyacrylate compound as a main component and leveling agents containing a fluorine atom-containing compound as a main component.

Examples of the leveling agent containing a polyacrylate compound as a main component include “BYK-350”, “BYK-352” “BYK-353”, “BYK-354”, “BYK-355”, “BYK-358N”, “BYK-361N”, “BYK-380”, “BYK-381” and “BYK-392” (manufactured by BYK-Chemie GmbH).

Examples of the leveling agent containing a fluorine atom-containing compound as a main component include “MEGAFAC (registered trademark) R-08”, “MEGAFAC (registered trademark) R-30”, “MEGAFAC (registered trademark) R-90”, “MEGAFAC (registered trademark) F-410”, “MEGAFAC (registered trademark) F-411”, “MEGAFAC (registered trademark) F-443”, “MEGAFAC (registered trademark) F-445”, “MEGAFAC (registered trademark) F-470”, “MEGAFAC (registered trademark) F-471”, “MEGAFAC (registered trademark) F-477”, “MEGAFAC (registered trademark) F-479”, “MEGAFAC (registered trademark) F-482” and “MEGAFAC (registered trademark) F-483” (DIC Corporation); “Surflon (registered trademark) S-381”, “Surflon (registered trademark) S-382”, “Surflon (registered trademark) S-383”, “Surflon (registered trademark) S-393”, “Surflon (registered trademark) SC-101”, “Surflon (registered trademark) SC-105”, “Surflon (registered trademark) KH-40” and “Surflon (registered trademark) SA-100” (AGC Seimi Chemical Co., Ltd.); “E1830” and “E5844” (Daikin Fine Chemical Laboratory Co., Ltd.); and “EFTOP EF301”, “EFTOP EF303”, “EFTOP EF351” and “EFTOP EF352” (Mitsubishi Materials Electronic Chemicals Co., Ltd.).

The content of the leveling agent in the orientation layer is preferably not less than 0.001 parts by mass and not more than 5 parts by mass, more preferably not less than 0.005 parts by mass and not more than 1 part by mass, and furthermore preferably not less than 0.01 parts by mass and not more than 0.5 parts by mass to 100 parts by mass of the solid matter in the composition for forming an orientation layer to form an orientation layer. In terms of easiness in orientation of the polymerizable liquid crystal compound in the optically anisotropic layer and superiority in the optically compensating characteristic of the resulting optically anisotropic layer, the content of the leveling agent is preferably not less than 0.001 parts by mass and not more than 5 parts by mass.

The orientation layer preferably has solvent resistance so as not to be dissolved by application of the polymerizable liquid crystal composition and heat resistance to a heat treatment for removal of the solvent or orientation of the polymerizable liquid crystal compound. Examples of the orientation layer include an orientation layer containing an orienting polymer, and a photo-orientation layer.

### [Orientation Layer Containing Orienting Polymer]

Examples of the orienting polymer include polyamides and gelatins having amide bonds in the molecules, polyimides having imide bonds in the molecules and their hydrolyzed products, polyamic acids, polyvinyl alcohol, alkyl-modified polyvinyl alcohol, polyacrylamide, polyoxazole, polyethyleneimine, polystyrene, polyvinyl pyrrolidone, polyacrylic acid and polyacrylic acid esters. Among them, preferable is polyvinyl alcohol. Two or more kinds of the orienting polymers may be used in combination.

The orientation layer containing the orienting polymer is usually formed by applying a composition for forming an orientation layer in which the orienting polymer is dissolved in a solvent to a substrate and removing the solvent to form a coating layer, or by applying a composition for forming an orientation layer to a substrate, removing the solvent to form a coating layer, and rubbing the coating layer (rubbing method).

Examples of the solvent include water, alcohol solvents such as methanol, ethanol, ethylene glycol, isopropyl alcohol, propylene glycol, methyl cellosolve, butyl cellosolve and propylene glycol monomethyl ether, ester solvents such as ethyl acetate, butyl acetate, ethylene glycol methyl ether acetate, γ-butyrolactone, propylene glycol methyl ether acetate and ethyl lactate, ketone solvents such as acetone, methyl ethyl ketone, cyclopentanone, cyclohexanone, methyl amyl ketone and methyl isobutyl ketone, aliphatic hydrocarbon solvents such as pentane, hexane and heptane, aromatic hydrocarbon solvents such as toluene and xylene, nitrile solvents such as acetonitrile, ether solvents such as tetrahydrofuran and dimethoxyethane, and chlorinated hydrocarbon solvents such as chloroform and chlorobenzene. These solvents may be used alone or in combination of two or more kinds of them.

The concentration of the orienting polymer in the composition for forming an orientation layer may be within a range where an orienting polymer material can be completely dissolved in a solvent, and is preferably not less than 0.1% and not more than 20% and more preferably not less than 0.1% and not more than 10% in terms of the solid matter in the solution.

Commercially available orienting materials may be use as they are as the composition for forming an orientation layer.

Examples of the commercially available orienting materials include Sunever (registered trademark, manufactured by Nissan Chemical Industries, Ltd.) and Optmer (registered trademark, manufactured by JSR Corporation).

Examples of the method for applying the composition for forming an orientation layer to a substrate include known methods of coating methods such as a spin coating method, an extrusion method, a gravure coating method, a die coating method, a slit coating method, a bar coating method and an applicator method as well as a printing method such as flexography. When the present optical film is produced by a continuous production method in the roll to roll manner as described below, a gravure coating method, a die coating method, or a printing method such as flexography is usually employed for the coating method.

Examples of the method for removing the solvent contained in the composition for forming an orientation layer include a natural drying method, a ventilation drying method, heat drying and a reduced-pressure drying method. In the case of heat drying, the temperature is usually not lower than 60° C. and not higher than 160° C., and preferably not lower than 80° C. and not higher than 140° C.

In order to provide the orientation layer with orientation regulation force, rubbing may be carried out if necessary (rubbing method). An example of the method for providing orientation regulation force by rubbing method include a method for bringing into contact with a rotating rubbing roll with a rubbing fabric wound thereon a layer of an orienting polymer that is formed on the substrate surface by applying the composition for forming an orientation layer and annealing the applied composition.

### [Photo-orientation Layer]

A photo-orientation layer is usually obtained by applying a composition for forming an orientation layer containing a polymer or monomer having a photo-reactive group as well as a solvent to a substrate and irradiating the substrate with light (preferably polarized UV). A photo-orientation layer is preferable because the direction of the orientation regulation force can be arbitrarily controlled by selecting the polarizing direction of light to be irradiated.

The photo-reactive group means a group that provides liquid crystal orientation capability by irradiation with light, and examples thereof include groups that involve in a photoreaction such as an orientation inducing or isomerization reaction, a dimerization reaction, a photo-crosslinking reaction or a photo decomposition reaction of molecules generated by irradiation with light to result in the liquid crystal orientation. Among them, preferable are groups that involve in a dimerization reaction or a photo-crosslinking reaction in terms of superiority in orientation. The photo-reactive group is preferably a group having an unsaturated bond, and more preferably a group having a double bond. Particularly preferable is a group having at least one selected from the group consisting of a carbon-carbon double bond (C═C bond), a carbon-nitrogen double bond (C═N bond), a nitrogen-nitrogen double bond (N═N bond) and a carbon-oxygen double bond (C═O bond).

Examples of the photo-reactive group having a C═C bond include a vinyl group, a polyene group, stilbene group, a stilbazole group, a stilbazolium group, a chalcone group and a cinnamoyl group. Examples of the photo-reactive group having a C═N bond include an aromatic Schiff base group and a group having a structure of an aromatic hydrazone or the like. Examples of the photo-reactive group having a N═N bond include an azobenzene group, an azonaphthalene group, an aromatic heterocyclic azo group, a bisazo group, a formazan group and a group having an azoxybenzene structure. Examples of the photo-reactive group having a C═O bond include a benzophenone group, a coumarin group, an anthraquinone group and a maleimide group. These groups may have a substituent such as an alkyl group, an alkoxy group, an aryl group, an allyloxy group, a cyano group, an alkoxycarbonyl group, a hydroxyl group, a sulfonic acid group or a haloalkyl group.

A cinnamoyl group or a chalcone group is preferable in terms of relative low polarized light irradiation dose needed for the photo-orientation and easiness in obtaining a photo-orientation layer excellent in heat stability and temporal stability. Particularly, a monomer or polymer having photo-reactivity preferably has a cinnamoyl group which forms a cinnamic acid structure in the terminal of the side chain of the monomer or polymer.

A photo-orientation inducing layer can be formed on the substrate by applying the composition for forming an orientation layer to the substrate. Examples of a solvent contained in the composition include those which are the same as the solvent contained in the composition for forming an orientation layer to form an orientation layer containing the orienting polymer, and the solvent may be selected properly in accordance with the solubility of the polymer or monomer having a photo-reactive group.

The content of the polymer or monomer having a photo-reactive group in the composition for forming an orientation layer may be adjusted properly depending on the kind of the polymer or monomer and the thickness of a photo-orientation layer of interest, and is preferably at least 0.2% by mass and more preferably not less than 0.3% by mass and not more than 10% by mass. The composition for forming an orientation layer may contain a polymer material such as polyvinyl alcohol or polyimide, and a photosensitizer to an extent that the characteristics of the photo-orientation layer are not significantly deteriorated.

Examples of the method for applying the composition for forming an orientation layer to the substrate include methods which are the same as the methods for applying the composition for forming an orientation layer to form the orientation layer containing the orienting polymer to the substrate. Examples of the method for removing the solvent from the composition for forming an orientation layer to be applied include methods which are the same as the methods for removing the solvent from the composition for forming an orientation layer to form the orientation layer containing the orienting polymer.

Irradiation with polarized light may be in a manner of directly irradiating a composition for forming an orientation layer applied to a substrate and from which the solvent is removed with polarized light or in a manner of irradiating polarized light from the substrate side and transmitting the polarized light. The polarized light is preferably parallel light. The wavelength of the polarized light for irradiation is preferably in a wavelength range where the photo-reactive group of the polymer or the monomer can absorb the light energy. Specifically, UV (ultraviolet) with a wavelength of not shorter than 250 nm and not longer than 400 nm is preferable. The irradiation dose of UV is usually not less than 1 mJ/cm² and not more than 500 mJ/cm², preferably not less than 10 mJ/cm² and not more than 200 mJ/cm², and more preferably not less than 10 mJ/cm² and not more than 100 mJ/cm². Examples of a light source to be used for the irradiation with polarized light include a xenon lamp, a high pressure mercury lamp, a very high pressure mercury lamp, a metal halide lamp and ultraviolet laser such as KrF or ArF. A high pressure mercury lamp, a very high pressure mercury lamp, or a metal halide lamp is preferable in terms of high light emission intensity of ultraviolet rays with a wavelength of 313 nm. Polarized UV can be irradiated by irradiating light from the light source through a proper polarizing film. As such a polarizing film, usable are a polarizing filter, a polarizing prism such as a Glan-Thompson prism or a Glan-Taylor prism, and a wire-grid type polarizing film.

When rubbing or irradiation with polarized light is carried out, a plurality of regions (patterns) different in liquid crystal orientation can be formed by masking.

The thickness of the orientation layer is usually not less than 10 nm and not more than 10000 nm, preferably not less than 10 nm and not more than 1000 nm, and more preferably not less than 10 nm and not more than 700 nm.

### [Method for Producing Optical Film]

A method for continuously producing the present optical film will be described. As a preferable method for continuously producing the present optical film, there is a roll-to-roll type method. The following is an example of a representative production method.

The representative production method is a method including successively the steps of:

(1) preparing a roll of a substrate wound on a core;
(2) continuously feeding the substrate from the roll;
(3) forming an orientation layer on the substrate;
(4) forming an optically anisotropic layer on the orientation layer to obtain an optical film; and
(5) continuously winding the obtained optical film on a second roll to obtain a second roll.

FIG. 1 shows a schematic diagram of one example of the present optical film. FIG. 1B shows the present optical film 100 obtained by laminating an orientation layer 1 and an optically anisotropic layer 2 in this order on a substrate 3.

The present optical film 100 having no orientation layer 1 and no substrate 3 can be obtained by transferring the optically anisotropic layer 2 of the present optical film to another substrate 3′ to thereby remove the substrate 3 and the orientation layer 1. The present optical film having no substrate is shown in FIG. 1A. Further, the present optical film having no substrate can be obtained by removing the substrate 3′.

When the optically anisotropic layer is composed of a layer A and a layer B, the optically anisotropic layer in FIGS. 1A and 1B may be considered to be an optically anisotropic layer composed of two layers of the layer A and the layer B. In this case, the order of the layer A and the layer B is not a matter. Further, an orientation layer may exist between the layer A and the layer B.

When the optically anisotropic layer has a configuration including a layer A21 and a layer B22, the respective layers may be laminated on both surfaces of the substrate 3. FIG. 1C shows a schematic diagram of the present optical film having optically anisotropic layers on both surfaces of the substrate 3. FIG. 1C shows a configuration of the present optical film 100 where the layer A21 and the layer B22 are directly formed, respectively, on each of the orientation layers 1.

Further, the respective layers may be laminated successively on the substrate 3 by transferring. In this case, the layer A or the layer B may be formed on an orientation layer containing a leveling agent by polymerizing a polymerizable liquid crystal compound, the other layer may be formed using a stretched film, and these layers may be transferred successively to the substrate 3; or the layer A and the layer B may be formed on an orientation layer containing a leveling agent by polymerizing a polymerizable liquid crystal compound, and then these layers may be transferred successively to the substrate 3.

### [Circularly Polarizing Plate]

The combination of the present optical film and a polarizing film can give a circularly polarizing plate (hereinafter, may be referred to as the present circularly polarizing plate) comprising the present optical film and the polarizing film. The present optical film and the polarizing film are usually stuck by an adhesive, preferably an active energy ray-curing adhesive. In the following explanation, a polarizing film and a polarizing plate having protection film(s) on either one or both surfaces of a polarizing film are collectively referred to as a polarizing plate.

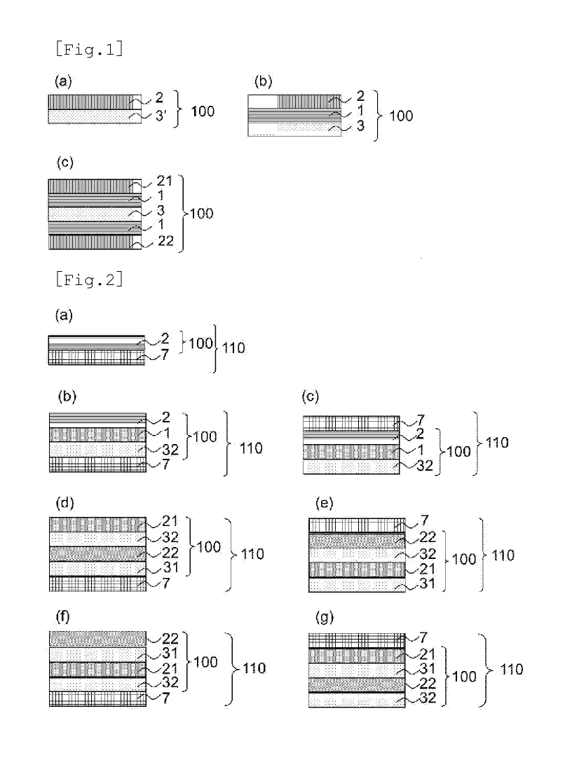

When an optically anisotropic layer is composed of only a monolayer and has only one slow axis, it is preferable to set the transmission axis of the polarizing plate substantially at 450 to the slow axis (optical axis) of the optically anisotropic layer of the present optical film. The substantially 45° usually means within a range of 45±5°. FIG. 2 shows a schematic diagram of one example of the present circularly polarizing plate 110.

The polarizing plate which the present circularly polarizing plate has as shown in FIG. 2 may be one having a protection film on one surface of the polarizing film or one having protection films on both surfaces of the polarizing film. The optically anisotropic layer may be composed of two layers of a layer A and a layer B.

FIG. 2B shows the present circularly polarizing plate 110 obtained by laminating the present optical film 100 and a polarizing plate 7, and the present optical film 100 is a circularly polarizing plate having a substrate 32, an orientation layer 1, and an optically anisotropic layer 2 in this order from the side near the polarizing plate 7.

FIG. 2C shows the present circularly polarizing plate 110 obtained by laminating the present optical film 100 and the polarizing plate 7, and the present optical film 100 is a circularly polarizing plate having the optically anisotropic layer 2, the orientation layer 1, and the substrate 32 in this order from the side near the polarizing plate 7.

In FIGS. 2B and 2C, the substrate 32 also functions as a protection film for protecting one surface of the polarizing film.

FIG. 2A shows the present polarizing plate obtained by laminating the present optical film 100 having no substrate and the polarizing plate 7. The circularly polarizing plate 110 shown in FIG. 2A can be obtained by transferring the present optical film 100 to the polarizing plate 7. Examples of a method for sticking the present optical film having no substrate to the polarizing plate include a method for sticking the present optical film from which a substrate is removed to the polarizing plate with an adhesive and a method for sticking the present optical film having a substrate to the polarizing plate with an adhesive and thereafter removing the substrate. In this case, the adhesive may be applied to the side of the optically anisotropic layer which the present optical film has or to the side of the polarizing plate. The orientation layer between the substrate and the optically anisotropic layer may be removed together with the substrate.

A substrate having functional groups forming a chemical bond with the orientation layer on the surface forms a chemical bond with the orientation layer and tends to become difficult to be removed. Accordingly, when the substrate is peeled off and removed, the substrate preferably has a few functional groups which form a chemical bond with the orientation layer on the substrate surface. Further, the substrate is also preferably a substrate that is not subjected to a surface treatment to form functional groups which form a chemical bond with the orientation layer on the substrate surface.

The orientation layer having functional groups for forming a chemical bond with the substrate tends to have a high sticking force between the substrate and the orientation layer. Accordingly, when the substrate is peeled off and removed, the orientation layer preferably has a few functional groups which form a chemical bond with the substrate. A composition for forming an orientation layer thus preferably contains no reagent that crosslinks the substrate and the orientation layer, and further preferably contains no solvent that dissolves the substrate.

The optically anisotropic layer having functional groups for forming a chemical bond with the orientation layer tends to have a high sticking force between the orientation layer and the optically anisotropic layer. Accordingly, when the orientation layer is removed together with the substrate, the optically anisotropic layer preferably has a few functional groups which form a chemical bond with the orientation layer. A polymerizable liquid crystal composition thus preferably contains no reagent that crosslinks the orientation layer and the optically anisotropic layer.

FIGS. 2D to 2G show configurations comprising an optically anisotropic layer composed of the layer A and the layer B and obtained by laminating the present optical film having two sheets of substrate.

When an optically anisotropic layer is composed of the layer A and the layer B, the position for laminating a polarizing plate is limited.

Specifically, when a layer A having a retardation of λ/4 and a layer B having a retardation of λ/2 are laminated, first, the layer B is formed in such a manner that the slow axis of the layer B forms an angle of 750 to the absorption axis of the polarizing plate, and next the layer A is formed in such a manner that the slow axis of the layer A forms an angle of 15° to the absorption axis of the polarizing plate. The lamination in such a position makes the circularly polarizing plate to be obtained exhibit a function as a broad band λ/4 plate. The axis angle forming the layer A and the layer B is not limited, and as described in, for example, JP-A-2004-126538, it has been already known that the function as a broad band λ/4 plate can be exhibited even if the slow axis angle of the layer A and the layer B to the absorption axis of the polarizing plate is adjusted to 30° and −30° or 45° and −45°. Accordingly, it is possible to laminate the layers by a desired method.

The present circularly polarizing plate can be incorporated in various display devices and can be particularly effectively incorporated in an organic electroluminescent (EL) display device, an inorganic electroluminescent (EL) display device, and an organic electroluminescent display device having a touch panel.

### [Polarizing Plate]

The polarizing film which the above-mentioned polarizing plate has may be a film having a polarizing function, and known polarizing films can be used. Examples of the polarizing film include a stretched film in which a pigment having absorption anisotropy is adsorbed and a film in which a film coated with a pigment having absorption anisotropy (JP-A-2012-33249) is included as a polarizing film. Examples of the pigment having absorption anisotropy include dichroic pigments.

The thickness of the stretched film in which a pigment having absorption anisotropy is adsorbed is preferably 5 to 40 μm. The film coated with a pigment having absorption anisotropy is preferable as it is thinner, but if the thickness is too thin, the strength tends to be lowered and the processability tends to be inferior. The thickness of the film coated with a pigment having absorption anisotropy is usually not more than 20 μm, preferably not more than 5 μm, and more preferably not less than 0.5 μm and not more than 3 μm.

The polarizing plate can be obtained by laminating a transparent protection film on at least one surface of the polarizing film obtained in the above-mentioned manner by an adhesive. As the transparent protection film, a transparent film which is the same as the substrate described above can be used preferably, and the optical film of the present invention can also be used.

### <Adhesive>

Examples of an adhesive to be used for producing the circularly polarizing plate, polarizing plate, etc., include known adhesives such as a pressure-sensitive adhesive, a water-based adhesive and an active energy ray-curing type adhesive.

The pressure-sensitive adhesive is obtained by radically polymerizing an acrylic monomer mixture containing a (meth)acrylic acid ester as a main component and a small amount of a (meth)acrylic monomer having a functional group in the present of a polymerization initiator. Particularly, an acrylic resin with a glass transition temperature Tg of not higher than 0° C. and an acrylic pressure-sensitive adhesive containing a crosslinking agent can be preferably used.

Examples of the method to be employed for forming a pressure-sensitive adhesive layer on the present optical film include a method for preparing a peelable film as a substrate, forming a pressure-sensitive adhesive layer by applying a pressure-sensitive adhesive composition to the substrate, and transferring the resulting pressure-sensitive adhesive layer to the surface of the present optical film; and a method for forming a pressure-sensitive adhesive layer by directly applying a pressure-sensitive adhesive composition to the surface of the present optical film surface.

The thickness of the pressure-sensitive adhesive layer is preferably not less than 5 μm and not more than 50 μm, and more preferably not less than 5 μm and not more than 30 μm. The adjustment of the thickness of the pressure-sensitive adhesive layer to not more than 30 μm improves the adhesive property in high temperature and high humidity conditions. The possibility of occurrence of brittles and separation between a display and the pressure-sensitive adhesive layer tends to be low and the re-workability tends to be improved. Further, the adjustment of the thickness to not less than 5 μm improves durability to dimensional changes because the pressure-sensitive adhesive layer can change with following the dimensional changes of the polarizing plate to which the layer is stuck.

As the water-based adhesive, commonly used is a composition containing a polyvinyl alcohol-based resin or a urethane resin as a main component and further a crosslinking agent or a curable compound such as an isocyanate-based compound or an epoxy compound in order to improve the adhesive property.

Examples of the method for forming a water-based adhesive layer on the present optical film include a method for forming an adhesive layer by directly applying a water-based adhesive composition to the present optical film surface. The water-based adhesive can be injected between the polarizing layer and the present optical film, thereafter a thermal crosslinking reaction can be promoted while water is evaporated by heating to provide a sufficient adhesive property between the polarizing layer and the present optical film. The thickness of the water-based adhesive layer is usually not less than 0.001 μm and not more than 5 μm, preferably not less than 0.01 μm and not more than 2 μm, and more preferably not more than 1 μm. If the adhesive layer is too thick, the polarizing plate tends to be inferior in appearance.

The active energy ray-curing type adhesive may be one which can be cured by irradiation with active energy rays and bond the polarizing plate and the present optical film with strength sufficient for practical use. Examples thereof include a cationically polymerizable active energy ray-curing type adhesive containing an epoxy compound and a cationic polymerization initiator; a radically polymerizable active energy ray-curing type adhesive containing an acrylic curing component and a radical polymerization initiator; an active energy ray-curing type adhesive containing both of a cationically polymerizable curing component such as an epoxy compound and a radically polymerizable curing component such as an acrylic compound and further a cationic polymerization initiator and a radical polymerization initiator; and an electron beam curing type adhesive which is an active energy ray-curing type adhesive containing no initiator and cured by irradiation with electron beam. The radically polymerizable active energy ray-curing type adhesive containing an acrylic curing component and a radical polymerization initiator and the cationically polymerizable active energy ray-curing type adhesive containing an epoxy compound and a cationic polymerization initiator are preferable.

Active energy rays can be defined as energy rays that can decompose a compound generating active species and thus generate active species. Examples of such active energy rays include visible light, ultraviolet rays, infrared rays, x-rays, α-rays, β-rays, γ-rays and electron beams.

Examples of the method for forming an active energy ray-curing type adhesive layer on the present optical film include a method for directly applying an active energy ray-curing type adhesive composition to the surface of the present optical film to form an active energy ray-curing type adhesive layer. The thickness of the adhesive layer is usually not less than 0.001 μm and not more than 5 μm, preferably not less than 0.01 μm and not more than 2 μm, and more preferably not more than 1 μm. If the adhesive layer is too thick, the polarizing plate tends to be inferior in appearance.

Examples of a light source to be used for polymerization curing of the adhesive by irradiation with active energy rays in the present invention include a low pressure mercury lamp, a middle pressure mercury lamp, a high pressure mercury lamp, a very high pressure mercury lamp, a xenon lamp, a halogen lamp, a carbon arc lamp, a tungsten lamp, a gallium lamp, an excimer laser, an LED light source emitting light in a wavelength range of 380 to 440 nm, a chemical lamp, a black light lamp, a microwave excitation mercury lamp and a metal halide lamp. In terms of stability of energy and convenience of apparatus, an ultraviolet light source having a light emission distribution in a wavelength range of not more than 400 nm is preferable.

### [Display Device]

The present optical film and the present circularly polarizing plate can be used for various display devices.

A display device is a device having display elements and includes a light-emitting element or a light-emitting device as a light-emitting source. Examples of the display device include a liquid crystal display device, an organic electroluminescent (EL) display device, an inorganic electroluminescent (EL) display device, a touch panel display device, electron emission display devices (e.g., a field emission display device (FED) and a surface-conduction electron-emitter display device (SED)), electronic paper (a display device using electronic ink or electrophoretic element), a plasma display device, a projection-type display device (e.g., a grating light valve (GLV) display device and a display device with a digital micromirror device (DMD)), and a piezoelectric ceramic display. The liquid crystal display device includes any mode of transmission type liquid crystal display devices, transflective liquid crystal display devices, reflective liquid crystal display devices, direct-viewing liquid crystal display devices, projection-type liquid crystal display devices, etc. Such a display device may be a display device that displays two-dimensional images or a stereoscopic display device that displays three-dimensional images. The present circularly polarizing plate can be particularly effectively incorporated in an organic electroluminescent (EL) display device and an inorganic electroluminescent (EL) display device, and the present optical film and the present circularly polarizing plate can be effectively incorporated in a liquid crystal display device and a touch panel display device.

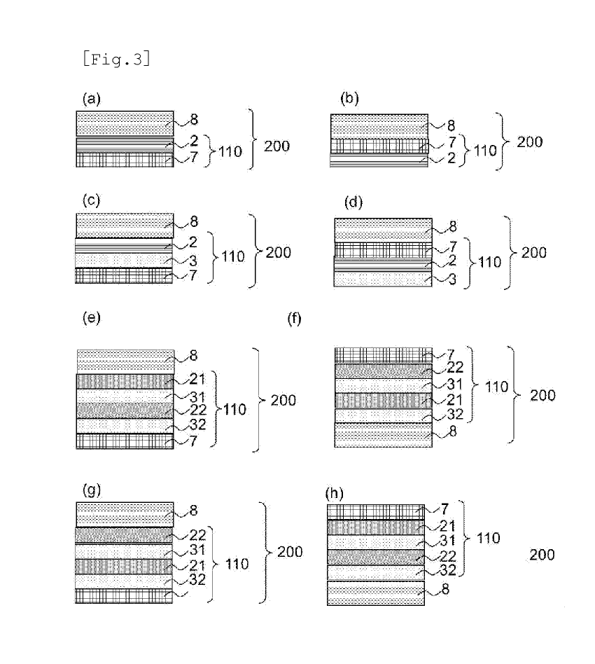

FIG. 3 is a schematic diagram showing one example of an organic EL display device 200 having the circularly polarizing plate.

FIG. 3A shows an organic EL display device 200 obtained by laminating the polarizing plate 7 constituting the present circularly polarizing plate 110, the optically anisotropic layer 2, and an organic EL panel 8 in this order. FIG. 3B shows an organic EL display device 200 with a lamination order which is different from that in FIG. 3A such that the optically anisotropic layer 2 constituting the present circularly polarizing plate 110, the polarizing plate 7, and the organic EL panel 8 are laminated in this order.

Examples of the method for laminating the polorizing plate the present optical film, and the organic EL panel include a method for sticking the present circularly polarizing plate obtained by laminating the polarizing plate and the present optical film to the organic EL panel and a method for sticking the present optical film to the organic EL panel and further sticking the polarizing plate to the surface of the present optical film. For the sticking, an adhesive is usually used.

For example, the organic EL display device 200 shown in FIG. 3A can be produced by applying an adhesive to the surface of the optically anisotropic layer 2 of the present circularly polarizing plate 110 shown in FIG. 2A and sticking the organic EL panel 8 thereto. The organic EL display device 200 shown in FIG. 3A can be also produced by applying an adhesive to the surface of the optically anisotropic layer 2 of the present optical film shown in FIG. 1B, sticking the organic EL panel 8 thereto, removing the substrate 3 and the orientation layer 1 of the present optical film, applying an adhesive to the surface of the optically anisotropic layer 2 to be appeared by removing the substrate, and sticking the polarizing plate 7.

The organic EL display device 200 shown in FIG. 3C is an organic EL display device including the organic EL panel 8, the optically anisotropic layer 2, the substrate 3, and the polarizing plate 7 in this order. The organic EL display device 200 shown in FIG. 3D is an organic EL display device including the organic EL panel 8, the polarizing plate 7, the optically anisotropic layer 2, and the substrate 3 in this order.

FIGS. 3E to 3H show organic EL devices obtained in the case of using a layer including the layer A and the layer B as optically anisotropic layer.

### EXAMPLES

Hereinafter, the present invention will be described further in detail by way of Examples. In Examples, the symbol “%” and the word “part(s)” denote “% by mass” and “part(s) by mass”, respectively, unless otherwise specified.

ZF-14 manufactured by ZEON CORPORATION was used as a cycloolefin polymer film (COP).

AGF-B10 manufactured by Kasuga Electric Works Ltd. was used as a corona treatment apparatus.

Using the corona treatment apparatus, a corona treatment was carried out once in conditions of an output power of 0.3 kW and a treatment speed of 3 m/minute.

SPOT CURE SP-7 equipped with a polarizing film unit, which is manufactured by Ushio, Inc., was used as a polarized UV irradiation apparatus.

LEXT manufactured by OLYMPUS CORPORATION was used as a laser microscope.

UNICURE VB-15201 BY-A manufactured by Ushio, Inc. was used as a high pressure mercury lamp.

A retardation value was measured by KOBRA-WR manufactured by Oji Scientific Instruments.

A thickness measurement was carried out using Ellipsometer M-220 manufactured by JASCO Corporation.

### Example 1

### Preparation of Composition for Forming Orientation Layer

The following components were mixed, and the resulting mixture was stirred at 80° C. for 1 hour to obtain a composition for forming an orientation layer (1-1). The following photo-orientation material was synthesized by the method described in JP-A-2013-33248. This photo-orientation material is a solid matter in the composition for forming an orientation layer.

### Photo-Orientation Material (5 Parts):

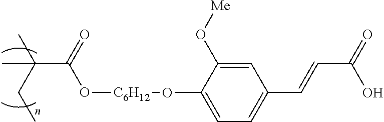

### Solvent (95 Parts): Cyclopentanone

The following additives were added in accordance with Table 1 to the composition for forming an orientation layer (1-1) prepared with the above-mentioned composition to obtain compositions for an orientation layer (1-2) to (1-5). The compositions for an orientation layer (1-2) to (1-4) contained BYK-361N and the composition for an orientation layer (1-5) contained Megafac F-477.

### <Leveling Agent>

BYK-361 N: Polyacrylate compound, manufactured by BYK-Chemie GmbH

Megafac F-477: Fluorine atom-containing compound, manufactured by DIC Corporation.

TABLE 1

| | | Content of leveling agent |
|---|---|---|
| | | to 100 parts by mass |
| | Leveling agent | of photo-orientation material |
| Composition for forming | BYK-361N | 0.01 |
| orientation layer (1-2) | | |
| Composition for forming | BYK-361N | 0.05 |
| orientation layer (1-3) | | |
| Composition for forming | BYK-361N | 0.1 |
| orientation layer (1-4) | | |
| Composition for forming | Megafac F-477 | 0.01 |
| orientation layer (1-5) | | |

### Preparation of Polymerizable Liquid Crystal Composition (A-1)

The following components were mixed, and the resulting mixture was stirred at 80° C. for 1 hour to obtain a polymerizable liquid crystal composition (A-1).

A polymerizable liquid crystal A1 and a polymerizable liquid crystal A2 were synthesized by the method described in JP-A-2010-31223.

### Polymerizable Liquid Crystal A1 (12.31 Parts):

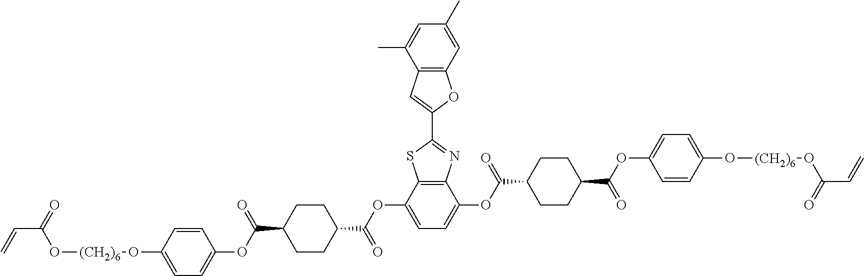

### Polymerizable Liquid Crystal A2 (0.86 Parts):

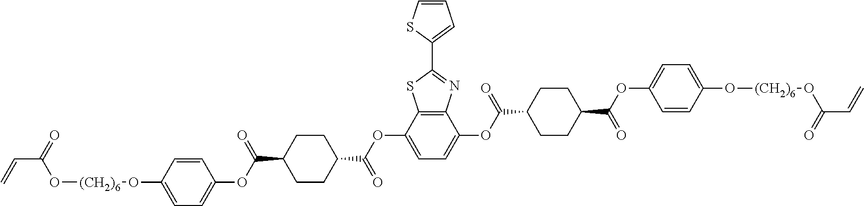

### Polymerization Initiator (0.73 Parts):

2-dimethylamino-2-benzyl-1-(4-morphorinophenyl)butan-1-one (Irgacure 369, manufactured by Ciba Specialty Chemicals Inc.)
Leveling agent (0.01 parts): polyacrylate compound (BYK-361N; manufactured by BYK-Chemie GmbH)
Solvent: Cyclopentanone (52.2 parts), N-methyl-2-pyrrolidone (NMP)(34.8 parts)

### Example 1

### Production of Optically Anisotropic Layer

A cycloolefin polymer film (COP) (ZF-14, manufactured by ZEON CORPORATION) was once treated by a corona treatment apparatus (AGF-B10, manufactured by Kasuga Electric Works Ltd.) in conditions of an output power of 0.3 kW and a treatment speed of 3 m/minute. The composition for forming an orientation layer (1-2) was applied to the corona-treated surface by a bar coater, dried at 80° C. for 1 minute, and then exposed to polarized UV at an integrated light quantity of 100 mJ/cm² using a polarized UV irradiation device (SPOT CURE SP-7; manufactured by Ushio, Inc.). The thickness of the resulting orientation layer was measured by an Ellipsometer to find the results shown in Table 2. Successively, the polymerizable liquid crystal composition (A-1) was applied onto the orientation layer by a bar coater, dried at 120° C. for 1 minute, followed by irradiation with ultraviolet rays (in nitrogen atmosphere, wavelength: 365 nm, integrated light quantity at a wavelength of 365 nm: 1000 mJ/cm²) by high pressure mercury lamp (UNICURE VB-15201 BY-Amanufactured by Ushio, Inc.) to form an optical film 1 including an optically anisotropic layer. The retardation values of the resulting optical film 1 at a wavelength of 450 nm and a wavelength of 650 nm were measured to find that the retardation values were in a range of 120 to 150 nm, and the relations between the in-plane retardation values at each wavelength were as follows.

Re(450)/Re(550)=0.85

Re(650)/Re(550)=1.03

That is, the optically anisotropic layer had optical characteristics defined by the following formulas (1), (2) and (4). Since the retardation value of the COP at a wavelength of 550 nm is approximately 0, this does not affect the relations of the in-plane retardation values.

Re(450)/Re(550)≦1.00 (1)

1.00≦Re(650)/Re(550) (2)

100 nm<Re(550)<160 nm (4)

The resulting optical film 1 was sandwiched between two polarizing plates in such a manner that the angle formed between the slow axis of the optical film 1 and the absorption axis of the polarizing plate was 45° and the resulting product was observed while being put on back light under the crossed-Nicol condition of the absorption axes of the two polarizing plates being set orthogonally to each other (corresponding to black display). At this time, if retardation unevenness is observed, it is rated as x and if retardation unevenness is not observed, it is rated as ◯, and the observation results of the retardation unevenness in the optical film 1 are shown in Table 2.

### Example 2

An optical film 1 including an optically anisotropic layer was obtained in the same manner as in Example 1, except that the composition for forming an orientation layer (1-3) was used as the composition for forming an orientation layer. The thickness of the orientation layer and the observation results of the retardation unevenness in the optical film 1 are shown in Table 2.

### Example 3

An optical film 1 including an optically anisotropic layer was obtained in the same manner as in Example 1, except that the composition for forming an orientation layer (1-4) was used as the composition for forming an orientation layer. The thickness of the orientation layer and the observation results of the retardation unevenness in the optical film 1 are shown in Table 2.

### Example 7

An optical film 1 including an optically anisotropic layer was obtained in the same manner as in Example 1, except that the composition for forming an orientation layer (1-5) was used as the composition for forming an orientation layer. The thickness of the orientation layer and the observation results of the retardation unevenness in the optical film 1 are shown in Table 2.

### Comparative Example 1

An optical film 1 including an optically anisotropic layer was obtained in the same manner as in Example 1, except that the composition for forming an orientation layer (1-1) was used as the composition for forming an orientation layer. The thickness of the orientation layer and the observation results of the retardation unevenness in the optical film 1 are shown in Table 2.

TABLE 2

| | | Content of | | |
|---|---|---|---|---|
| | | leveling | | |
| | | agent to | Thickness | |
| | | 100 parts | of | |
| | | by mass | photo- | Retardation |
| | Composition for | of photo- | orientation | unevenness |
| | forming | orientation | layer | of optical |
| Example No. | orientation film | material | (nm) | film 1 |
| Example 1 | Composition (1-2) | 0.01 | 670 | ◯ |
| Example 2 | Composition (1-3) | 0.05 | 590 | ◯ |
| Example 3 | Composition (1-4) | 0.1 | 600 | ◯ |
| Example 7 | Composition (1-5) | 0.01 | 600 | ◯ |
| Comparative | Composition (1-1) | 0 | 600 | X |
| Example 1 | | | | |

### Example 4

### Production of Optically Anisotropic Layer

A polyethylene terephthalate film (PET) (Diafoil T140E25, manufactured by Mitsubishi Plastics, Inc.) was once treated by a corona treatment apparatus (AGF-B10, manufactured by Kasuga Electric Works Ltd.) in conditions of an output power of 0.3 kW and a treatment speed of 3 m/minute. The composition for forming an orientation layer (1-2) was applied to the corona-treated surface by a bar coater, dried at 80° C. for 1 minute, and then exposed to polarized UV at an integrated light quantity of 100 mJ/cm² using a polarized UV irradiation device (SPOT CURE SP-7; manufactured by Ushio, Inc.). The thickness of the resulting orientation layer was measured by an Ellipsometer to find the results shown in Table 3. Successively, the polymerizable liquid crystal composition (A-1) was applied onto the orientation layer by a bar coater, dried at 120° C. for 1 minute, followed by irradiation with ultraviolet rays (in nitrogen atmosphere, wavelength: 365 nm, integrated light quantity at a wavelength of 365 nm: 1000 mJ/cm²) by high pressure mercury lamp (UNICURE VB-15201 BY-A manufactured by Ushio, Inc.) to form an optical film 1 including an optically anisotropic layer. Further, after a pressure-sensitive adhesive was stuck onto the optically anisotropic layer of the optical film 1, a cycloolefin polymer film (COP) (ZF-14, manufactured by ZEON CORPORATION) that was once treated by a corona treatment apparatus (AGF-B10, manufactured by Kasuga Electric Works Ltd.) in conditions of an output power of 0.3 kW and a treatment speed of 3 m/minute was stuck to the pressure-sensitive adhesive. Thereafter, the PET film of the substrate was peeled to obtain an optical film 2 in which the optically anisotropic layer was transferred onto the COP film. At this time, the transferred layer was only the optically anisotropic layer and the orientation layer existed on the PET film of the substrate. The retardation values of the resulting optical film 2 at a wavelength of 450 nm and a wavelength of 650 nm were measured to find that the retardation values were in a range of 120 to 150 nm, and the relations between the in-plane retardation values at each wavelength were as follows.

Re(450)/Re(550)=0.85

Re(650)/Re(550)=1.03

That is, the optically anisotropic layer had optical characteristics defined by the following formulas (1), (2), and (4). Since the retardation value of the COP at a wavelength of 550 nm is approximately 0, this does not affect the relations of the in-plane retardation values.

Re(450)/Re(550)≦1.00 (1)

1.00≦Re(650)/Re(550) (2)

100 nm<Re(550)<160 nm (4)

The resulting optical film 2 was sandwiched between two polarizing plates in such a manner that the angle formed between the slow axis of the optical film 2 and the absorption axis of the polarizing plate was 45° and the resulting product was observed while being put on back light under the crossed-Nicol condition of the absorption axes of the two polarizing plates being set orthogonally to each other (corresponding to black display). At this time, if retardation unevenness is observed, it is rated as x and if retardation unevenness is not observed, it is rated as ◯, and the observation results of the retardation unevenness in the optical film 2 are shown in Table 3.

### Example 5

An optical film 2 including an optically anisotropic layer was obtained in the same manner as in Example 4, except that the composition for forming an orientation layer (1-3) was used as the composition for forming an orientation layer. The thickness of the orientation layer and the observation results of the retardation unevenness in the optical film 2 are shown in Table 3.

### Example 6

An optical film 2 including an optically anisotropic layer was obtained in the same manner as in Example 4, except that the composition for forming an orientation layer (1-4) was used as the composition for forming an orientation layer. The thickness of the orientation layer and the observation results of the retardation unevenness in the optical film 2 are shown in Table 3.

### Example 8

An optical film 2 including an optically anisotropic layer was obtained in the same manner as in Example 4, except that the composition for forming an orientation layer (1-5) was used as the composition for forming an orientation layer. The thickness of the orientation layer and the observation results of the retardation unevenness in the optical film 2 are shown in Table 3.

### Comparative Example 2

An optical film 2 including an optically anisotropic layer was obtained in the same manner as in Example 4, except that the composition for forming an orientation layer (1-1) was used as the composition for forming an orientation layer. The thickness of the orientation layer and the observation results of the retardation unevenness in the optical film 2 are shown in Table 3.

TABLE 3

| | | Content of | | |
|---|---|---|---|---|
| | | leveling | | |
| | | agent to | Thickness | |
| | | 100 parts | of | |
| | | by mass | photo- | Retardation |
| | Composition for | of photo- | orientation | unevenness |
| | forming | orientation | layer | of optical |
| Example No. | orientation layer | material | (nm) | film 2 |
| Example 4 | Composition (1-2) | 0.01 | 670 | ◯ |
| Example 5 | Composition (1-3) | 0.05 | 590 | ◯ |
| Example 6 | Composition (1-4) | 0.1 | 600 | ◯ |
| Example 8 | Composition (1-5) | 0.01 | 600 | ◯ |
| Comparative | Composition (1-1) | 0 | 600 | X |
| Example 2 | | | | |

The optical film of the present invention has no in-plane retardation unevenness at the time of black display and is excellent in suppression of light leakage, and thus is useful as a member for a display device.

1. An optical film having a photo-orientation layer containing a leveling agent and an optically anisotropic layer.

2. The optical film according to claim 1, wherein a content of the leveling agent in the orientation layer is not less than 0.001 parts by mass and not more than 5 parts by mass to 100 parts by mass of a solid matter in a composition for forming an orientation layer to form an orientation layer.

3. The optical film according to claim 1, wherein the orientation layer has a thickness of not less than 10 nm and not more than 1000 nm.

4. The optical film according to claim 1, wherein the orientation layer is a photo-orientation layer.

5. The optical film according to claim 1, wherein the orientation layer includes a structure derived from a compound having a cinnamoyl group.

6. The optical film according to claim 1, wherein the optically anisotropic layer has optical characteristics defined by the formulas (1) and (2):
Re(450)/Re(550)≦1.00 (1)
1.00≦Re(650)/Re(550) (2)
wherein, Re(λ) represents an in-plane retardation value to light with a wavelength of λ nm.

7. The optical film according to claim 1, wherein the optically anisotropic layer has an optical characteristic defined by the formula (3):
100 nm<Re(550)<160 nm (3)
wherein, Re(550) represents an in-plane retardation value at a wavelength of 550 nm.

8. The optical film according to claim 1, wherein the optically anisotropic layer contains a polymer of one or more polymerizable liquid crystal compounds.

9. The optical film according to claim 1, wherein the optically anisotropic layer has a thickness of not more than 20 μm.

10. A circularly polarizing plate comprising a layer including at least the optically anisotropic layer of the optical film according to claim 1 and a polarizing film.

11. The circularly polarizing plate according to claim 10, wherein the layer including at least the optically anisotropic layer and the polarizing plate are bonded to each other with an active energy ray-curing adhesive or a water-based adhesive.

12. An organic EL display device comprising the circularly polarizing plate according to claim 10.

13. A touch panel display device comprising the circularly polarizing plate according to claim 10.

14. A method for producing an optical film having an orientation layer containing a leveling agent and an optically anisotropic layer formed on the orientation layer, the method comprising the step of generating orientation regulation force on the orientation layer by irradiation of not less than 10 mJ/cm² and not more than 200 mJ/cm² of ultraviolet rays.
